(19) United States
(12) Patent Application Publication
(10) Pub. No.: US 2001/0015404 A1
(43) Pub. Date: Aug. 23, 2001

(54) Solid-state image-sensing device

(75) Inventors: Kenji Takada, Itami-Shi (JP); Yoshio Hagihara, Amagasaki-Shi (JP)

Correspondence Address: SIDLEY AUSTIN BROWN & WOOD, 717 NORTH HARWOOD, SUITE 3400, DALLAS, TX, 75201, US

(73) Assignee: MINOLTA CO., LTD.

(21) Appl. No.: 09/774,212

(22) Filed: Jan. 30, 2001

(30) Foreign Application Priority Data
Feb. 18, 2000 (JP) 2000-046700
Mar. 21, 2000 (JP) 2000-083202

(51) Int. Cl. H01L 27/00

(52) U.S. Cl. 250/208.1

(57) ABSTRACT

In a solid-state image-sensing device, when light is incident on a phototransistor PTr, the pn junction between the base and emitter thereof causes a current to flow in the base of the phototransistor PTr in proportion to the amount of incident light. Through amplification, this base current causes an emitter current to flow as a photocurrent, and thus a voltage logarithmically proportional to the amount of incident light appears at the gate of a MOS transistor T1 that is made to operate in a subthreshold region. A voltage obtained through integration of the thus logarithmically converted voltage appears at the node “a”, and, when a MOS transistor T6 is turned on, an output current corresponding to the voltage at the node “a” is delivered to an output signal line.

This application is based on Japanese Patent Applications Nos. 2000-046700 and 2000-083202 filed respectively on Feb. 18, 2000 and Mar. 21, 2000, the contents of which are hereby incorporated by reference.

### BACKGROUND OF THE INVENTION

1. Field of the Invention

The present invention relates to a solid-state image-sensing device, and particularly to a solid-state image-sensing device having pixels arranged in a two-dimensional array.

2. Description of the Prior Art

Two-dimensional solid-state image-sensing devices are used in various applications. A two-dimensional solid-state image-sensing device has pixels arranged in a matrix (two-dimensional array), and those pixels each include a photoelectric conversion element (photosensitive element) such as a photodiode and a means for transferring the photoelectric charge generated in the photoelectric conversion element to an output signal line. Such solid-state image-sensing devices are roughly grouped into CCD-type and MOS-type devices according to the means they use to read out (extract) the photoelectric charge generated in the photoelectric conversion element. CCD-type devices achieve transfer of photoelectric charge while accumulating it in potential wells, and thus has the disadvantage of a narrow dynamic range. On the other hand, MOS-type devices directly read out the electric charge accumulated in the pn-junction capacitance of the photodiodes through MOS transistors.

Now, how each pixel is configured in a conventional MOS-type solid-state image-sensing device will be described with reference to FIG. 33. As shown in this figure, a photodiode PD has its cathode connected to the gate of a MOS transistor T101 and to the source of a MOS transistor T102. The MOS transistor T101 has its source connected to the drain of a MOS transistor T103, and this MOS transistor T103 has its source connected to an output signal line VOUT. A direct-current voltage VPD is applied to the drain of the MOS transistor T101 and to the drain of the MOS transistor T102, and a direct-current voltage VPS is applied to the anode of the photodiode.

When light is incident on the photodiode PD, photoelectric charge is generated therein, and this electric charge is accumulated at the gate of the MOS transistor T101. In this state, when a pulse signal φV is fed to the gate of the MOS transistor T103 to turn this MOS transistor T103 on, a current proportional to the electric charge accumulated at the gate of the MOS transistor T101 flows through the MOS transistors T101 and T103 to the signal output line. In this way, it is possible to read as an output signal an output current that is proportional to the amount of incident light. After this signal has been read out, the MOS transistor T103 is turned off and thereby the MOS transistor T102 is turned on so that the gate voltage of the MOS transistor T101 will be initialized.

As described above, in a conventional MOS-type solid-state image-sensing device, in each pixel, the photoelectric charge generated in a photodiode PD and then accumulated at the gate of a MOS transistor is directly read out. This, however, leads to a narrow dynamic range and thus demands accurate control of the amount of exposure. Moreover, even if the amount of exposure is controlled accurately, the obtained image tends to suffer from flat blackness in dim portions thereof and saturation in bright portions thereof. Furthermore, photodiodes offer a low amplification factor when producing electric signals through photoelectric conversion, and thus the output signals they yield have low levels. This leads to an unsatisfactorily low SIN (signal-to-noise) ratio, and thus makes it impossible to obtain a high-quality image signal as a whole.

To overcome these problems, the assignee of the present invention once proposed a solid-state image-sensing device including a photodiode that generates a photocurrent proportional to the amount of incident light, a MOS transistor to which the generated photocurrent is fed, and a bias means that applies a bias to the MOS transistor so that the MOS transistor is brought into a state in which a subthreshold current flows therethrough, wherein the photocurrent is converted logarithmically (refer to United States Patent No. 4,973,833). This solid-state image-sensing device offers a wide dynamic range, but still suffers from unsatisfactory characteristics and S/N ratio under low-brightness conditions.

### SUMMARY OF THE INVENTION

An object of the present invention is to provide a solid-state image-sensing device that has its pixels so configured as to yield output signals with higher levels and that thus offers a high-quality image signal as a whole.

Another object of the present invention is to provide a solid-state image-sensing device that offers a wide dynamic range.

To achieve the above objects, according to one aspect of the present invention, a solid-state image-sensing device is provided with: a phototransistor, having a control electrode kept in a floating state, for producing an electric signal by amplifying a photocurrent that appears at the control electrode in proportion to the amount of incident light; and a first transistor, connected in series with the phototransistor, for receiving the electric signal amplified by the phototransistor. Here, the first transistor is made to operate in a subthreshold region so that the electric signal output from the phototransistor is so converted as to be fed out as a signal logarithmically proportional to the amount of incident light.

### BRIEF DESCRIPTION OF THE DRAWINGS

This and other objects and features of the present invention will become clear from the following description, taken in conjunction with the preferred embodiments with reference to the accompanying drawings in which:

FIG. 1 is a block circuit diagram illustrating the overall configuration of a two-dimensional solid-state image-sensing device embodying the invention;

FIGS. 2A and 2B are circuit diagrams of a portion of FIG. 1;

FIG. 3 is a circuit diagram showing the configuration of each pixel in a first embodiment of the invention;

FIG. 4 is a circuit diagram showing another example of the configuration of each pixel in the first embodiment;

FIG. 5 is a circuit diagram showing the configuration of each pixel in a second embodiment of the invention;

FIG. 6 is a circuit diagram showing the configuration of each pixel in a third embodiment of the invention;

FIG. 7 is a circuit diagram showing the configuration of each pixel in a fourth embodiment of the invention;

FIG. 8 is a circuit diagram showing the configuration of each pixel in a fifth embodiment of the invention;

FIG. 9 is a circuit diagram showing the configuration of each pixel in a sixth embodiment of the invention;

FIG. 10 is a timing chart of the signals fed to the individual circuit elements constituting each pixel in the sixth embodiment;

FIG. 11 is a circuit diagram showing the configuration of each pixel in a seventh embodiment of the invention;

FIG. 12 is a timing chart of the signals fed to the individual circuit elements constituting each pixel in the seventh embodiment;

FIG. 13 is a circuit diagram showing the configuration of each pixel in an eighth embodiment of the invention;

FIG. 14 is a timing chart of the signals fed to the individual circuit elements constituting each pixel in the eighth embodiment;

FIG. 15 is a circuit diagram showing the configuration of each pixel in a ninth embodiment of the invention;

FIG. 16 is a timing chart of the signals fed to the individual circuit elements constituting each pixel in the ninth embodiment;

FIG. 17 is a block circuit diagram illustrating the overall configuration of another two-dimensional solid-state image-sensing device embodying the invention;

FIG. 18 is a circuit diagram showing the configuration of each pixel in a tenth embodiment of the invention;

FIG. 19 is a timing chart of the signals fed to the individual circuit elements constituting each pixel in the tenth embodiment;

FIG. 20 is a circuit diagram showing the configuration of each pixel in an eleventh embodiment of the invention;

FIG. 21 is a timing chart of the signals fed to the individual circuit elements constituting each pixel in the eleventh embodiment;

FIG. 22 is a circuit diagram showing the configuration of each pixel in a twelfth embodiment of the invention;

FIG. 23 is a timing chart of the signals fed to the individual circuit elements constituting each pixel in the twelfth embodiment;

FIG. 24 is a circuit diagram showing the configuration of each pixel in a thirteenth embodiment of the invention;

FIG. 25 is a timing chart of the signals fed to the individual circuit elements constituting each pixel in the thirteenth embodiment;

FIG. 26 is a timing chart of the signals fed to the individual circuit elements constituting each pixel in the thirteenth embodiment;

FIG. 27 is a circuit diagram showing the configuration of each pixel in a fourteenth embodiment of the invention;

FIG. 28 is a timing chart of the signals fed to the individual circuit elements constituting each pixel in the fourteenth embodiment;

FIG. 29 is a timing chart of the signals fed to the individual circuit elements constituting each pixel in the fourteenth embodiment;

FIG. 30 is a circuit diagram showing the configuration of each pixel in a fifteenth embodiment of the invention;

FIG. 31 is a timing chart of the signals fed to the individual circuit elements constituting each pixel in the fifteenth embodiment;

FIG. 32 is a timing chart of the signals fed to the individual circuit elements constituting each pixel in the fifteenth embodiment; and

FIG. 33 is a circuit diagram showing the configuration of each pixel of a conventional two-dimensional solid-state image-sensing device.

### DESCRIPTION OF THE PREFERRED EMBODIMENTS

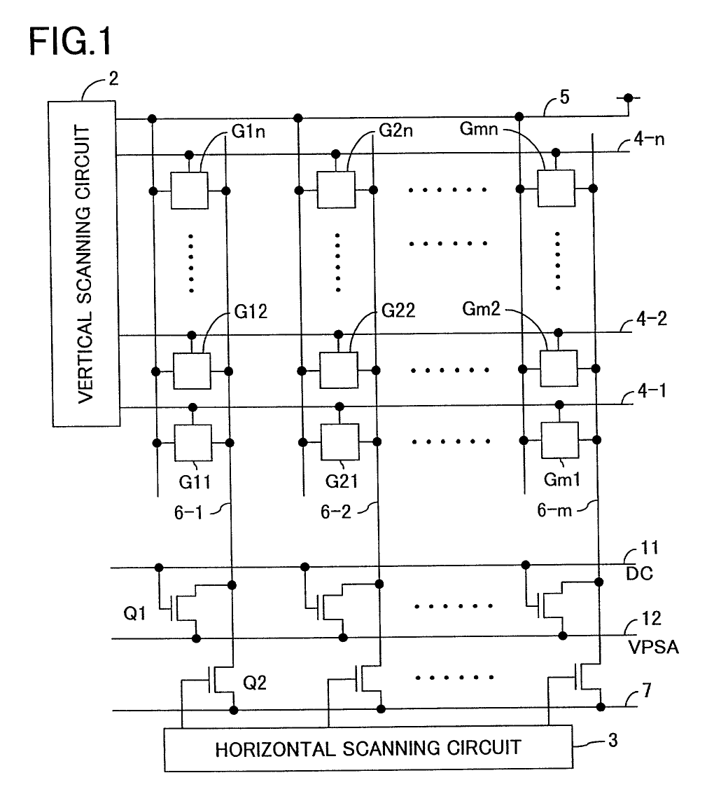

First Example of Pixel Configuration FIG. 1 schematically shows the configuration of a portion of a twodimensional MOS-type solid-state image-sensing device embodying the invention. In this figure, reference symbols G11 to Gmn represent pixels that are arranged in a two-dimensional array (in a matrix). Reference numeral 2 represents a vertical scanning circuit, which scans lines (rows) 4-1, 4-2, . . . , 4-n sequentially. Reference numeral 3 represents a horizontal scanning circuit, which reads out, sequentially pixel by pixel in a horizontal direction, the signals fed from the individual pixels to output signal lines 6-1, 6-2, . . . , 6-m as a result of photoelectric conversion performed in those pixels. Reference numeral 5 represents a power line. The individual pixels are connected not only to the lines 4-1, 4-2, . . . , 4-n, to the output signal lines 6-1, 6-2, . . . , 6-m, and to the power line 5 mentioned above, but also to other lines (for example clock lines and bias supply lines). These other lines, however, are omitted in FIG. 1, and are shown in individual embodiments of the invention shown in FIG. 3 and the following figures.

As shown in FIG. 1, for each of the output signal lines 6-1, 6-2, . . . , 6-m, a pair of N-channel MOS transistors Q1 and Q2 is provided. Here, a description will be given only with respect to the output signal line 6-1 as their representative. The MOS transistor Q1 has its gate connected to a direct-current voltage line 11, has its drain connected to the output signal line 6-1, and has its source connected to a line 12 of a direct-current voltage VPSA. On the other hand, the MOS transistor Q2 has its drain connected to the output signal line 6-1, has its source connected to a signal line 7 serving as a final destination line, and has its gate connected to the horizontal scanning circuit 3.

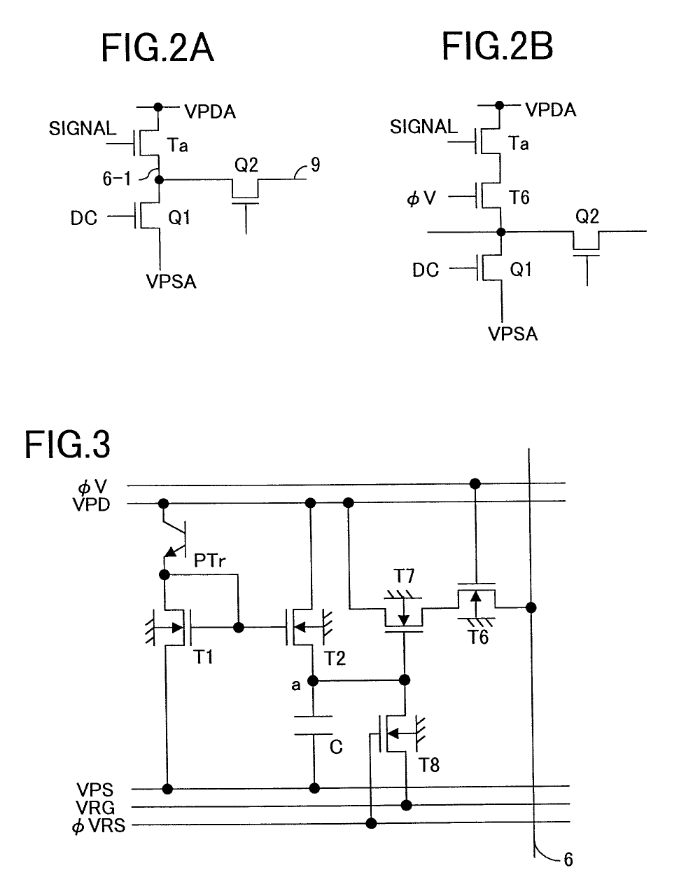

As will be described later, the pixels G11 to Gmn are each provided with an N-channel MOS transistor Ta that outputs a signal proportional to the photoelectric charge generated in each pixel. How this MOS transistor Ta is connected to the above-mentioned MOS transistor Q1 is shown in FIG. 2A. This MOS transistor Ta corresponds to the MOS transistor T7 in the first and second embodiments, and corresponds to the MOS transistor T2 in the third to ninth embodiments. Here, the direct-current voltage VPSA connected to the source of the MOS transistor Q1 and the direct-current voltage VPDA connected to the drain of the MOS transistor Ta fulfill the relation VPDA>VPSA, where the direct-current voltage VPSA is equal to, for example, the ground-level voltage. In this circuit configuration, the signal from a pixel is fed to the gate of the upper-stage MOS transistor Ta, and a direct-current voltage DC is kept applied to the gate of the lower-stage MOS transistor Q1. Thus, the lower-stage MOS transistor Q1 is equivalent to a resistor or constant-current source, and therefore the circuit shown in FIG. 2A forms an amplifier circuit of a source-follower type. Here, it can safely be assumed that, as a result of amplification, the MOS transistor Ta outputs a current.

The MOS transistor Q2 is controlled by the horizontal scanning circuit 3 so as to function as a switching device. As will be described later, in all of the embodiments of the invention shown in FIG. 3 and the following figures, within each pixel, another N-channel MOS transistor T6 functioning as a switch is provided. If this MOS transistor T6 is illustrated explicitly, the circuit shown in FIG. 2A has, more precisely, a circuit configuration as shown in FIG. 2B. Specifically, the MOS transistor T6 is inserted between the MOS transistor Q1 and the MOS transistor Ta. Here, the MOS transistor T6 serves to select a row, and the MOS transistor Q2 serves to select a column. It is to be noted that the circuit configurations shown in FIGS. 1, 2A, and 2B are common to the first to ninth embodiments of the invention described hereinafter.

The circuit configuration shown in FIGS. 2A and 2B permits the signal to be output with a high gain. Accordingly, even in a case where the photocurrent generated in a photosensitive element is converted natural-logarithmically to obtain a wider dynamic range and thus the output signal obtained is comparatively low, this amplifier circuit amplifies the signal so as to make it sufficiently high and thus easier to process in the succeeding signal processing circuit (not shown). Here, the MOS transistor Q1 that serves as the load resistor of the amplifier circuit is provided within each pixel; however, such transistors may be provided, instead, one for each of the output signal lines 6-1, 6-2, . . . , 6-m to which the pixels arranged in columns are collectively connected column by column. This helps reduce the number of load resistors or constant-current sources required, and thereby reduce the area occupied by the amplifying circuits on a semiconductor chip.

First Embodiment

A first embodiment of the invention, which is applicable to each pixel of the first example of pixel configuration shown in FIG. 1, will be described below with reference to the drawings. FIG. 3 is a circuit diagram showing the configuration of each pixel provided in the solid-state image-sensing device of this embodiment.

In FIG. 3, an npn-type phototransistor PTr constitutes a photosensitive portion (photoelectric conversion portion). This phototransistor PTr has its emitter connected to the drain and gate of a MOS transistor T1 and to the gate of a MOS transistor T2. The MOS transistor T2 has its source connected to the gate of a MOS transistor T7 and to the drain of a MOS transistor T8, and the MOS transistor T7 has its source connected to the drain of a MOS transistor T6. The MOS transistor T6 has its source connected to an output signal line 6 (this output signal line 6 corresponds to the output signal lines 6-1, 6-2, . . . , 6-m shown in FIG. 1). The MOS transistors T1, T2, and T6 to T8 are all N-channel MOS transistors with their back gates grounded.

A direct-current voltage VPD is applied to the collector of the phototransistor PTr and to the drains of the MOS transistors T2 and T7. A direct-current voltage VPS is applied to the source of the MOS transistor T1 and also through a capacitor C to the source of the MOS transistor T2. A direct-current voltage VRG is applied to the source of the MOS transistor T8. A signal φVRS is fed to the gate of the MOS transistor T8. A signal φV is fed to the gate of the MOS transistor T6. The MOS transistors T1 and T2 are both so biased as to operate in a subthreshold region.

The base of the phototransistor PTr is kept in a floating state, i.e. a state in which no voltage is applied thereto. In this phototransistor PTr, a base current appears in proportion to the amount of light incident on the pn junction between the base and emitter thereof, and this base current, through amplification, causes an emitter current (hereafter called the photocurrent) to flow, which is fed as an electric signal to the drain of the MOS transistor T1. The phototransistor PTr amplifies the base current in such a way that the emitter current is about 100 times as high as the base current, and thus yields a higher photocurrent than a photodiode does.

When light is incident on the phototransistor PTr, a photocurrent appears therein, and, due to the subthreshold characteristics of MOS transistors, a voltage natural-logarithmically proportional to the photocurrent appears at the gates of the MOS transistors T1 and T2. This voltage causes a current to flow through the MOS transistor T2, so that an amount of electric charge equivalent to the value obtained by natural-logarithmically converting the integral of the photocurrent is accumulated in the capacitor C. That is, a voltage natural-logarithmically proportional to the integral of the photocurrent appears at the node “a” between the capacitor C and the source of the MOS transistor T2. Here, the MOS transistors T6 and T8 remain off.

In this state, the pulse signal φV is fed to the gate of the MOS transistor T6 to turn this transistor T6 on. This causes a current proportional to the voltage at the gate of the MOS transistor T7 to be delivered through the MOS transistors T6 and T7 to the output signal line 6. Now, the voltage at the gate of the MOS transistor T7 is equal to the voltage at the node “a”, and therefore the current thus delivered to the output signal line 6 is natural-logarithmically proportional to the integral of the photocurrent.

In this way, it is possible to read out a signal (the output current) proportional to the logarithm of the amount of incident light. After this signal has been read out, the MOS transistor T6 is turned off, and a high-level signal is fed as the signal φVRS to the gate of the MOS transistor T8 to turn this MOS transistor T8 on. This initializes the capacitor C and the voltage at the node “a” in preparation for the next image-sensing operation.

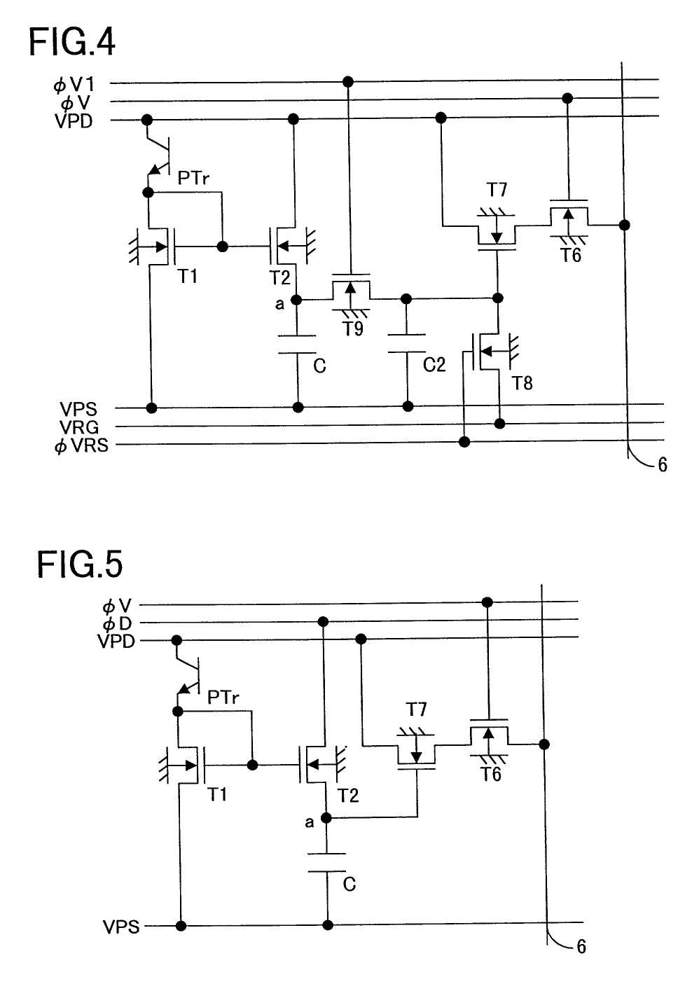

As shown in FIG. 4, the pixel may be so configured as to further include, between the capacitor C and the MOS transistor T8, another MOS transistor T9 having its drain connected to the capacitor C and having its source connected to the drain of the MOS transistor T8 and another capacitor C2 having one end connected to the source of the MOS transistor T9. In this case, a signal φV1 is fed to the gate of the MOS transistor T9 to turn this MOS transistor T9 on so that the electric charge accumulated in the capacitor C is transferred to the capacitor C2, and thereafter the MOS transistor T9 is turned off so that, while the MOS transistor T6 is reading out the signal, the capacitor C starts the next integration operation. This make it possible to perform integration simultaneously in all the pixels.

Second Embodiment

A second embodiment of the invention, which is applicable to each pixel of the first example of pixel configuration shown in FIG. 1, will be described below with reference to the drawings. FIG. 5 is a circuit diagram showing the configuration of each pixel provided in the solid-state image-sensing device of this embodiment. In the following description, such circuit elements, signal lines, and others as serve the same purposes as in the pixel shown in FIG. 3 are identified with the same reference numerals or symbols, and their detailed explanations will not be repeated.

As shown in FIG. 5, in this embodiment, initialization of the capacitor C and the voltage at the node “a” is achieved by feeding a signal φD to the drain of the MOS transistor T2. This makes it possible to omit the MOS transistor T8. In other respects, the pixel of this embodiment is configured in the same manner as that of the first embodiment (FIG. 3). Here, in a period in which the signal φD is at a high level, the capacitor C performs integration; in a period in which the signal φD is at a low level, the electric charge accumulated in the capacitor C is discharged through the MOS transistor T2, so that the voltage at the capacitor C, and thus the voltage at the gate of the MOS transistor T7, is initialized (i.e. reset) to a voltage approximately equal to the low-level voltage of the signal φD. In this embodiment, the omission of the MOS transistor T8 contributes to a simpler circuit configuration.

In this embodiment, first, the signal φD is turned to a high level (for example, a voltage approximately equal to the direct-current voltage VPD), so that an amount of electric charge equivalent to the value obtained by natural-logarithmically converting the integral of the photocurrent is accumulated in the capacitor C. Then, with predetermined timing, the MOS transistor T6 is turned on, so that a current proportional to the voltage at the gate of the MOS transistor T7 is delivered through the MOS transistors T6 and T7 to the output signal line 6. Subsequently, the MOS transistor T6 is turned off, and the signal φD is turned to a low level (a voltage lower than the direct-current voltage VPS), so that the electric charge accumulated in the capacitor C is discharged through the MOS transistor T2 to the signal path of the signal φD. This initializes the capacitor C and the voltage at the node “a”.

Third Embodiment

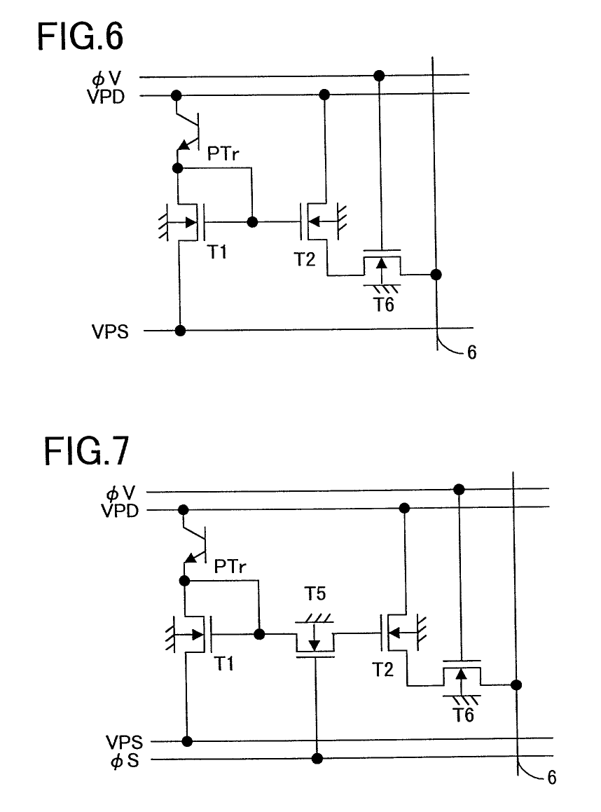

A third embodiment of the invention, which is applicable to each pixel of the first example of pixel configuration shown in FIG. 1, will be described below with reference to the drawings. FIG. 6 is a circuit diagram showing the configuration of each pixel provided in the solid-state image-sensing device of this embodiment. In the following description, such circuit elements, signal lines, and others as serve the same purposes as in the pixel shown in FIG. 5 are identified with the same reference numerals or symbols, and their detailed explanations will not be repeated.

As shown in FIG. 6, in this embodiment, the direct-current voltage VPD is applied to the drain of the MOS transistor T2, and the capacitor C and the MOS transistor T7 are omitted. The source of the MOS transistor T2 is connected to the drain of the MOS transistor T6. In other respects, the pixel of this embodiment is configured in the same manner as that of the second embodiment (FIG. 5).

In the circuit configured as described above, as the gate voltage of the MOS transistor T2 so varies as to be natural-logarithmically proportional to the photocurrent appearing in the phototransistor PTr, a current natural-logarithmically proportional to the photocurrent flows through the MOS transistor T2 as its drain current. In this state, when the signal φV is fed to the gate of the MOS transistor T6 to turn this MOS transistor T6 on, a current natural-logarithmically proportional to the photocurrent flows through the MOS transistors T2 and T6 as their drain currents and is delivered to the output signal line 6. As a result, the drain voltage of the MOS transistor Q1 (FIG. 2), which is determined by the on-state resistances of the MOS transistors T2 and Q1 and the current flowing therethrough, appears, as an output signal, on the output signal line 6. After this signal has been read out, the MOS transistor T6 is turned off.

In this embodiment, it is not necessary to perform integration of the photoelectric signal by the use of a capacitor C as performed in the second embodiment described previously, and thus no time is required for such integration, nor is it necessary to reset the capacitor C. This ensures accordingly faster signal processing. Moreover, in this embodiment, as compared with the second embodiment, the capacitor C and the MOS transistor T7 can be omitted, and this helps further simplify the circuit configuration and reduce the pixel size.

Fourth Embodiment

A fourth embodiment of the invention, which is applicable to each pixel of the first example of pixel configuration shown in FIG. 1, will be described below with reference to the drawings. FIG. 7 is a circuit diagram showing the configuration of each pixel provided in the solid-state image-sensing device of this embodiment. In the following description, such circuit elements, signal lines, and others as serve the same purposes as in the pixel shown in FIG. 6 are identified with the same reference numerals or symbols, and their detailed explanations will not be repeated.

As shown in FIG. 7, in this embodiment, a MOS transistor T5 is additionally provided that has its drain connected to the node between the gate and drain of the MOS transistor T1 and that has its source connected to the gate of the MOS transistor T2. A signal φS is fed to the gate of this MOS transistor T5. In other respects, the pixel of this embodiment is configured in the same manner as that of the third embodiment (FIG. 6). The MOS transistor T5 is, like the MOS transistor T1, an N-channel MOS transistor having its back gate grounded.

In the circuit configured as described above, first, the signal φS is turned to a low level so that, in all the individual pixels G11 to Gmn (FIG. 1) provided in the solid-state image-sensing device configured as shown in FIG. 1, the MOS transistor T5 is turned off. In this state, the phototransistor PTr produces a photocurrent proportional to the amount of incident light, and the gate voltage of the MOS transistor T1 is logarithmically proportional to the photocurrent. Next, with identical timing, the pulse signal φS is fed to the gate of the MOS transistor T5 of the pixels G11 to Gmn. When the pulse signal φS is turned to a high level, the MOS transistor T5 is turned on. This causes the voltage that appears in the MOS transistor T1 and that is logarithmically proportional to the photocurrent to be sampled and held at the gate of the MOS transistor T2. That is, the data of an image sensed at an identical time is sampled and held in the output-stage circuit of each pixel. When this voltage is sampled and held at the gate of the MOS transistor T2, the MOS transistor T5 is turned off.

Then, the vertical scanning circuit 2 (FIG. 1) feeds the pulse signal φV to the gate of the MOS transistor T6 provided in the individual pixels G11 to Gmn sequentially to turn on the MOS transistor T6 of each pixel sequentially, and the horizontal scanning circuit 3 (FIG. 1) permits the MOS transistor Q2 to be turned on, so that an output current logarithmically proportional to the photocurrent is delivered from one pixel after another to the output signal line 6. Here, in each pixel, when the MOS transistor T6 is turned on, a current proportional to the voltage that is sampled and held at the gate of the MOS transistor T2 and that is logarithmically proportional to the photocurrent flows through the MOS transistors T2 and T6 as their drain currents and is delivered as an output current to the output signal line 6. As a result, the drain voltage of the MOS transistor Q1 (FIG. 2), which is determined by the on-state resistances of the MOS transistors T2 and Q1 and the current flowing therethrough, appears, as an output signal, on the output signal line 6. After this signal has been read out, the MOS transistor T6 is turned off.

As described above, in this embodiment, after all the pixels of the solid-state image-sensing device have performed an image-sensing operation at an identical time, the vertical and horizontal scanning circuits control the individual pixels in such a way that the pixels sequentially output their output signals that as a whole carry the data of the image sensed at that identical time. This permits the solid-state image-sensing device to output as serial data an output signal carrying the data of an image sensed at an identical time. By obtaining an output signal as serial data in this way, it is possible to reproduce an image of which the data is free from temporal errors.

Fifth Embodiment

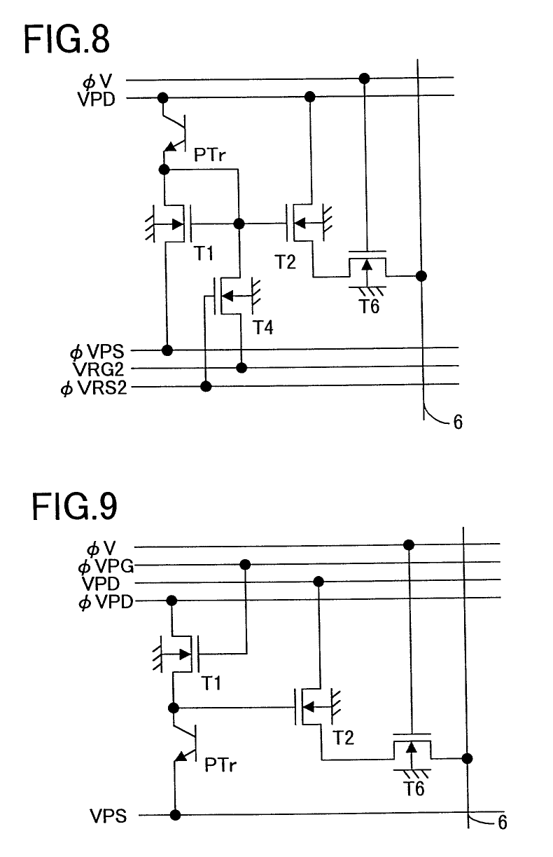

A fifth embodiment of the invention, which is applicable to each pixel of the first example of pixel configuration shown in FIG. 1, will be described below with reference to the drawings. FIG. 8 is a circuit diagram showing the configuration of each pixel provided in the solid-state image-sensing device of this embodiment. In the following description, such circuit elements, signal lines, and others as serve the same purposes as in the pixel shown in FIG. 6 are identified with the same reference numerals or symbols, and their detailed explanations will not be repeated.

As shown in FIG. 8, in this embodiment, a MOS transistor T4 is additionally provided that has its drain connected to the node between the drain of the MOS transistor T1 and the gate of the MOS transistor T2 and that receives at its source a direct-current voltage VPG2. A signal φVRS2 is fed to the gate of the MOS transistor T4. Moreover, a signal φVPS is fed to the source of the MOS transistor T1. In other respects, the pixel of this embodiment is configured in the same manner as that of the third embodiment (FIG. 6). The MOS transistor T4 is, like the MOS transistor T1, an N-channel MOS transistor having its back gate grounded.

In this embodiment, the voltage of the signal φVPS is switched to change the bias applied to the MOS transistor T1. This makes it possible to switch the operation mode of the pixel between a mode in which the output signal delivered to the output signal line 6 is natural-logarithmically proportional to the photocurrent and a mode in which the output signal delivered to the output signal line 6 is linearly proportional to the photocurrent. Here, the signal φVPS is a binary signal that is either at a high level that permits the MOS transistors T1 and T2 to operate in a subthreshold region or at a low level that is approximately equal to the direct-current voltage VPD. How the pixel operates in each mode will be described below.

(1) The Mode in Which the Photocurrent is Converted Natural-Logarithmically for Output

First, how the pixel operates when the signal φVPS is kept at a low level so that the MOS transistors T1 and T2 are so biased as to operate in a subthreshold region will be described. Here, the MOS transistor T4, receiving at its gate a low level as the signal φVRS2, is off, and therefore can be regarded as practically nonexistent.

When light is incident on the phototransistor PTr, a photocurrent appears therein, and, due to the subthreshold characteristics of MOS transistors, a voltage natural-logarithmically proportional to the photocurrent appears at the gates of the MOS transistors T1 and T2. This voltage tends to cause a current natural-logarithmically proportional to the photocurrent to flow through the MOS transistor T2 as its drain current, but, at this point, the MOS transistor T6 is off.

Next, the pulse signal φV is fed to the gate of the MOS transistor T6 to turn this MOS transistor T6 on. As a result, a current proportional to the voltage at the gate of the MOS transistor T2 flows through the MOS transistors T2 and T6 as their drain current and is delivered to the output signal line 6. The current thus delivered to the output signal line 6 is natural-logarithmically proportional to the photocurrent. After this signal (the output current) proportional to the logarithm of the amount of incident light has been read out, the MOS transistor T6 is turned off. In this mode, where the output current is so produced as to be natural-logarithmically proportional to the amount of incident light, the signal φVRS2 remains at a low level all the time.

(2) The Mode in Which the Photocurrent is Converted Linearly for Output

Next, how the pixel operates when the signal φVPS is kept at a high level so that the MOS transistor T1 is kept in a cut-off state will be described. Here, the MOS transistor T4, receiving at its gate a low level as the signal φVRS2, is off. In this state, when light is incident on the phototransistor PTr, a photocurrent appears therein. Here, capacitors are formed between the back gate and gate of the MOS transistor T1 and in the phototransistor PTr, and therefore the electric charge resulting from the photocurrent is accumulated at the gate and drain of the MOS transistor T1. Thus, the gate voltage of the MOS transistors T1 and T2 is proportional to the integral of the photocurrent.

Next, the pulse signal φV is fed to the gate of the MOS transistor T6 to turn this MOS transistor T6 on. As a result, a current proportional to the voltage at the gate of the MOS transistor T2 flows through the MOS transistors T2 and T6 as their drain current and is delivered to the output signal line 6. The voltage at the gate of the MOS transistor T2 is proportional to the integral of the photocurrent, and therefore the output current delivered to the output signal line 6 is linearly proportional to the photocurrent.

In this way, it is possible to read out a signal (the output current) proportional to the amount of incident light. After this signal has been read out, the MOS transistor T6 is turned off, and a high level is fed as the signal φVRS2 to the gate of the MOS transistor T4 to turn this MOS transistor T4 on. This initializes the phototransistor PTr, the drain voltage of the MOS transistor T1, and the gate voltage of the MOS transistors T1 and T2.

As described above, in this embodiment, it is possible to switch among a plurality of output characteristics patterns through simple potential manipulation. When the operation mode is switched from the logarithmic conversion mode to the linear conversion mode, it is preferable to perform the switching by first controlling the potential of the signal φVPS to switch the output and then making the MOS transistor T4 reset the MOS transistor T1 and other circuit elements. On the other hand, when the operation mode is switched from the linear conversion mode to the logarithmic conversion mode, it is not necessary to make the MOS transistor T4 reset the MOS transistor T1 and other circuit elements. The reason is that the carriers that are accumulated in the MOS transistor T1 because the MOS transistor T1 is not kept in a completely off state are canceled by carriers of the opposite polarity.

In this embodiment, the pixel may be so configured as to include, as in the first or second embodiment, a capacitor C (see FIG. 3 or 5) having one end connected to the source of the MOS transistor T2 and a MOS transistor T7 (see FIG. 3 or 5) having its gate connected to the source of the MOS transistor T2 and having its source connected to the drain of the MOS transistor T6 so that the pixel includes an integrator circuit in the output stage.

In this case, in the mode where the output current is produced through logarithmic conversion, the node “a” and the capacitor C are reset by using the MOS transistor T8 (see FIG. 3) or T2 (see FIG. 5). On the other hand, in the mode where the output current is produced through linear conversion, first the MOS transistor T1 and other circuit elements are reset by using the MOS transistor T4, and then the node “a” and the capacitor C are reset by using the MOS transistor T8 (see FIG. 3) or T2 (see FIG. 5).

Alternatively, in this embodiment, the pixel may be so configured as to include, as in the fourth embodiment, a MOS transistor T5 (see FIG. 7) having its source connected to the node between the gate and drain of the MOS transistor T1 and having its drain connected to the gate of the MOS transistor T2. In this case, when the MOS transistor T1 and other circuit elements are reset in the linear conversion mode, the MOS transistor T5 is turned on. Then, on completion of the resetting of the MOS transistor T1 and other circuit elements, the MOS transistor T5 is turned off in preparation for the next image-sensing operation. The drain of the MOS transistor T4 may be connected to either the source or the drain of the MOS transistor T5.

Sixth Embodiment

A sixth embodiment of the invention, which is applicable to each pixel of the first example of pixel configuration shown in FIG. 1, will be described below with reference to the drawings. FIG. 9 is a circuit diagram showing the configuration of each pixel provided in the solid-state image-sensing device of this embodiment.

In FIG. 9, an npn-type phototransistor PTr constitutes a photosensitive portion (photoelectric conversion portion). This phototransistor PTr has its collector connected to the source of a MOS transistor T1 and to the gate of a MOS transistor T2. The MOS transistor T2 has its source connected to the drain of a MOS transistor T6, and this MOS transistor T6 has its source connected to an output signal line 6 (this output signal line 6 corresponds to the output signal lines 6-1, 6-2, . . . , 6-m shown in FIG. 1). The MOS transistors T1, T2, and T6 are all N-channel MOS transistors with their back gates grounded.

A direct-current voltage VPS is applied to the emitter of the phototransistor PTr. A signal φVPD is fed to the drain of the MOS transistor T1, and a signal φVPG is fed to the gate of the same MOS transistor T1. A direct-current voltage VPD is applied to the drain of the MOS transistor T2. A signal φV is fed to the gate of the MOS transistor T6.

The base of the phototransistor PTr is kept in a floating state, i.e. a state in which no voltage is applied thereto. In this phototransistor PTr, a base current appears in proportion to the amount of light incident on the pn junction between the base and emitter thereof, and this base current, through amplification, causes an emitter current (hereafter called the photocurrent) to flow, which is fed as an electric signal to the drain of the MOS transistor T1. The phototransistor PTr amplifies the base current in such a way that the emitter current is about 100 times as high as the base current, and thus yields a higher photocurrent than a photodiode does.

In this embodiment, by switching the voltage of the signal φVPG and thereby turning the MOS transistor T1 on and off, it is possible to switch the operation mode of the pixel between a mode in which the output signal delivered to the output signal line 6 is natural-logarithmically proportional to the photocurrent that the phototransistor PTr produces in proportion to the amount of incident light and a mode in which the output signal is linearly proportional to the photocurrent. How the pixel operates in each mode will be described below. Here, the signal φVPD is a binary voltage signal that takes either a “first voltage” that is approximately equal to the direct-current voltage VPD and that is fed to the MOS transistor T1 to make it operate in a subthreshold region when the photocurrent is converted natural-logarithmically or a “second voltage” that is used as an operating point of the MOS transistor T2 when the photocurrent is converted linearly.

(1) The Mode in Which the Photocurrent is Converted Natural-Logarithmically for Output

First, the signal φVPD is turned to the first voltage, and the signal φVPG is turned to a voltage that permits the MOS transistor T1 to operate in a subthreshold region. In this state, when light is incident on the phototransistor PTr, a photocurrent appears therein, and, due to the subthreshold characteristics of a MOS transistor, a voltage natural-logarithmically proportional to the photocurrent appears at the source of the MOS transistor T1 and thus at the gate of the MOS transistor T2. Here, the current that flows into the MOS transistor T1 through its source is determined by the number of holes that appear in the phototransistor PTr, and therefore, the more intense the incident light, the lower the source voltage of the MOS transistor T1.

When the voltage natural-logarithmically proportional to the photocurrent appears at the gate of the MOS transistor T2, then the signal φV is turned to a high level to turn the MOS transistor T6 on. Here, since the gate voltage of the MOS transistor T2 is natural-logarithmically proportional to the photocurrent, a current natural-logarithmically proportional to the photocurrent is delivered through the MOS transistors T2 and T6 to the output signal line 6. As a result, the drain voltage of the MOS transistor Q1 (FIG. 2), which is determined by the on-state resistances of the MOS transistors T2 and Q1 and the current flowing therethrough, appears, as an output signal, on the output signal line 6. After this signal proportional to the logarithm of the amount of incident light has been read out, the MOS transistor T6 is turned off in preparation for the next image-sensing operation.

(2) The Mode in Which the Photocurrent is Converted Linearly for Output

The signal φVPD is turned to the second voltage (or, provided that the circuit configuration is optimized so as to ensure proper operation of the MOS transistor T2, the signal φVPD may be left at the first voltage). The signal φVPG is, as a binary voltage signal, switched between two levels so that, when it is at a high level, the MOS transistor T1 is turned on and, when it is at a low level, the MOS transistor T1 is turned off. In the linear conversion mode, where the signals φVPD and φVPG are controlled in this way, an image-sensing operation and a reset operation are achieved as described below. Here, the MOS transistor T1 functions as a resetting transistor, and the MOS transistor T2 functions as a signal amplification transistor.

(2-a) Image-Sensing Operation

First, the signal φVPG is turned to a high level so that, through the MOS transistor T1, the gate voltage of the MOS transistor T2 is rest. Then, the signal φVPG is turned to a low level to turn the MOS transistor T1 off. In this state, a photocurrent flows through the phototransistor PTr, and this causes the gate voltage of the MOS transistor T2 to vary. Specifically, a current that is determined by the number of holes appearing in the phototransistor PTr is fed from the phototransistor PTr to the gate of the MOS transistor T2. Thus, the gate voltage of the MOS transistor T2 is linearly proportional to the photocurrent. Here, since the current that flows into the MOS transistor T2 through its gate is determined by the number of holes that appear in the phototransistor PTr, the more intense the incident light, the lower the gate voltage of the MOS transistor T2.

When the voltage linearly proportional to the photocurrent appears at the gate of the MOS transistor T2, then the signal φV is turned to a high level to turn the MOS transistor T6 on. Here, since the gate voltage of the MOS transistor T2 is proportional to the integral of the photocurrent, a current linearly proportional to the photocurrent is delivered through the MOS transistors T2 and T6 to the output signal line 6. After this signal (the output current) proportional to the amount of incident light has been read out, the MOS transistor T6 is turned off.

(2-b) Reset Operation

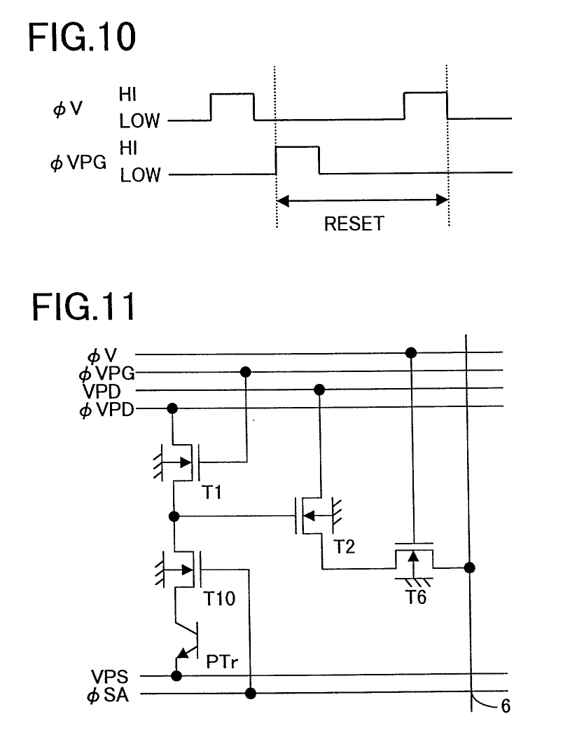

FIG. 10 is a timing chart showing how the relevant signals are controlled when each pixel is reset. After, as described above, the pulse signal φV is fed to the gate of the MOS transistor T6 and the output signal is read out, first, the pulse signal φVPG is turned to a high level to turn the MOS transistor T1 on. Here, the signal φVPD fed to the drain of the MOS transistor T1 is at the second voltage, and therefore a voltage corresponding to this second voltage is applied to the gate of the MOS transistor T2. Thus, the gate voltage of the MOS transistor T2 is reset to this voltage. After this resetting, the signal φVPG is turned to a low level to turn the MOS transistor T1 off.

Next, the pulse signal φV is fed to the gate of the MOS transistor T6, so that the output current produced when the gate voltage of the MOS transistor T2 is reset is delivered to the output signal line 6 so as to be read out as an output signal obtained at that time. This signal is to be used as compensation data with which to correct variations in sensitivity among the individual pixels resulting from variations in the characteristics, such as the threshold level, of the MOS transistor T2 and other circuit elements. After this compensation data has been read out, the MOS transistor T6 is turned off in preparation for the next image-sensing operation.

Seventh Embodiment

A seventh embodiment of the invention will be described below with reference to the drawings. FIG. 11 is a circuit diagram showing the configuration of each pixel provided in the solid-state image-sensing device of this embodiment. In the following description, such circuit elements, signal lines, and others as serve the same purposes as in the pixel shown in FIG. 9 are identified with the same reference numerals or symbols, and their detailed explanations will not be repeated.

As shown in FIG. 11, in this embodiment, a MOS transistor T10 is additionally provided that has its drain connected to the node between the source of the MOS transistor T1 and the gate of the MOS transistor T2 and that has its source connected to the collector of the phototransistor PTr. A signal φSA is fed to the gate of the MOS transistor T10. In other respects, the pixel of this embodiment is configured in the same manner as that of the sixth embodiment (FIG. 9). The MOS transistor T10 is, like the MOS transistors T1, T2, and T6, an N-channel MOS transistor having its back gate grounded.

Here, the signal φVPD is a ternary voltage signal that takes one of a “first voltage” that is approximately equal to the direct-current voltage VPD and that is fed to the MOS transistor T1 to make it operate in a subthreshold region in the logarithmic conversion mode so that the photocurrent is converted natural-logarithmically, a “second voltage” that is used as the operating point of the MOS transistor T2 when the photocurrent is converted linearly, and a “third voltage” that is approximately equal to the direct-current voltage VPS so as to permit detection of the variation in the threshold level of the MOS transistor T1 when the photocurrent is converted natural-logarithmically.

(1) The Mode in Which the Photocurrent is Converted Natural-Logarithmically for Output

(1-a) Image-Sensing Operation

The signal φVPD is turned to the first voltage so that the MOS transistor T1 operates in the subthreshold region, and the signal φSA that is fed to the gate of the MOS transistor T10 is turned to a high level to turn this MOS transistor T10 on. In this state, as in the sixth embodiment, when light is incident on the phototransistor PTr, a photocurrent appears therein, and, due to the subthreshold characteristics of a MOS transistor, a voltage natural-logarithmically proportional to the photocurrent appears at the source of the MOS transistor T1 and thus at the gate of the MOS transistor T2.

Next, the signal φV is turned to a high level to turn the MOS transistor T6 on. Here, since the gate voltage of the MOS transistor T2 is logarithmically proportional to the amount of the incident light, a current natural-logarithmically proportional to the photocurrent is delivered through the MOS transistors T2 and T6 to the output signal line 6. After this signal (the output current) natural-logarithmically proportional to the amount of incident light has been read out, the signal φV is turned to a low level to turn the MOS transistor T6 off.

(1-b) Sensitivity Variation Detection Operation

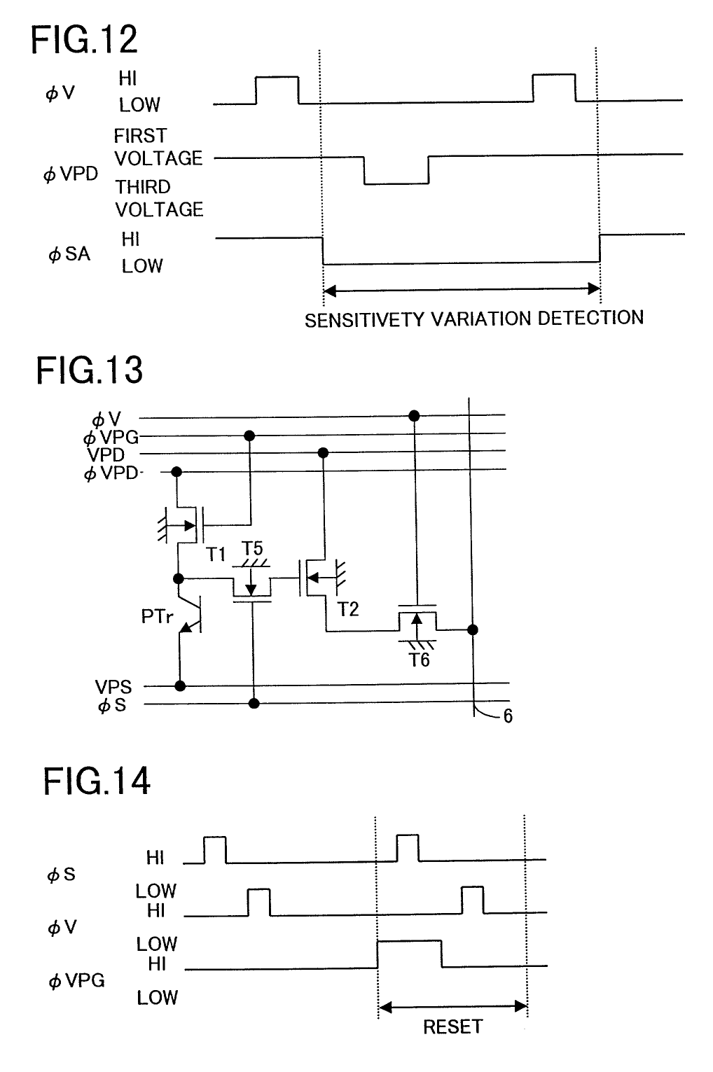

FIG. 12 is a timing chart showing how the relevant signals are controlled when the variation in sensitivity of each pixel is detected. After, as described above, the pulse signal φV is fed to the gate of the MOS transistor T6 and the output signal is read out, first, the signal φSA is turned to a low level to turn the MOS transistor T10 off. Then, the signal φVPD is turned to the third voltage so that negative electric charge is accumulated between the drain and source of the MOS transistor T1.

Next, the signal φVPD is turned back to the first voltage. As a result, part of the accumulated negative electric charge flows out to the signal line of the signal φVPD, and some negative electric charge remains accumulated at the source of the MOS transistor T1. The amount of negative electric charge accumulated here is determined by the gate-to-source threshold voltage of the MOS transistor T1. When this negative electric charge is accumulated at the source of the MOS transistor T1, the pulse signal φV is fed to the gate of the MOS transistor T6 so that an output signal is read out.

The output signal thus read out is to be used as compensation data with which to correct variations in sensitivity among the individual pixels resulting from variations in the characteristics, such as the threshold level, of the MOS transistor T1 and other circuit elements. Lastly, in preparation for the next image-sensing operation, the MOS transistor T6 is turned off, and then the signal φSA is turned to a high level to turn the MOS transistor T10 on.

(2) The Mode in Which the Photocurrent is Converted Linearly for Output

As in the sixth embodiment, the signal φVPD is turned to the second voltage. The signal φVPG is, as a binary voltage signal, switched between two levels so that, when it is at a high level, the MOS transistor T1 is turned on and, when it is at a low level, the MOS transistor T1 is turned off. The signal φSA is kept at a high level all the time, and therefore the MOS transistor T10 that receives at its gate the signal φSA remains on all the time. Thus, the MOS transistor T1 functions as a resetting transistor, and the MOS transistor T2 functions as a signal amplification transistor.

(2-a) Image-Sensing Operation

First, the signal φVPG is turned to a high level so that, through the MOS transistor T1, the gate voltage of the MOS transistor T2 is reset. Then, the signal φVPG is turned to a low level to turn the MOS transistor T1 off. In this state, as in the sixth embodiment, a photocurrent flows through the phototransistor PTr, and the gate voltage of the MOS transistor T2 is linearly proportional to the photocurrent.

Next, the signal φV is turned to a high level to turn the MOS transistor T6 on. Here, since the gate voltage of the MOS transistor T2 is proportional to the integral of the amount of incident light, a current linearly proportional to the photocurrent is delivered through the MOS transistors T2 and T6 to the output signal line 6. After this signal (the output current) proportional to the amount of incident light has been read, the MOS transistor T6 is turned off.

(2-b) Reset Operation

In the linear conversion mode, a reset operation is achieved, as in the sixth embodiment, by feeding in the relevant signals with the timing shown in the timing chart of FIG. 10. After, as described above, the pulse signal φV is fed to the gate of the MOS transistor T6 and the output signal is read out, first, the pulse signal φVPG is fed to the MOS transistor T1 to reset the gate voltage of the MOS transistor T2. Next, the pulse signal φV is fed to the gate of the MOS transistor T6, so that the output current produced when the gate voltage of the MOS transistor T2 is reset is delivered to the output signal line 6 so as to be read out as an output signal. The signal thus read out is used to detect the variation in sensitivity of each pixel. Then, the MOS transistor T6 is turned off in preparation for the next image-sensing operation.

Eighth Embodiment

An eighth embodiment of the invention will be described below with reference to the drawings. FIG. 13 is a circuit diagram showing the configuration of each pixel provided in the solid-state image-sensing device of this embodiment. In the following description, such circuit elements, signal lines, and others as serve the same purposes as in the pixel shown in FIG. 9 are identified with the same reference numerals or symbols, and their detailed explanations will not be repeated.

As shown in FIG. 13, in this embodiment, a MOS transistor T5 is additionally provided that has its drain connected to the source of the MOS transistor T1 and that has its source connected to the gate of the MOS transistor T2. A signal φS is fed to the gate of the MOS transistor T5. In other respects, the pixel of this embodiment is configured in the same manner as that of the sixth embodiment (FIG. 9). The MOS transistor T5 is, like the MOS transistors T1, T2, and T6, an N-channel MOS transistor having its back gate grounded.

In this embodiment, by switching the voltage of the signal φVPG and thereby turning the MOS transistor T1 on and off, it is possible to switch the operation mode of the pixel between a mode in which the output signal delivered to the output signal line 6 is natural-logarithmically proportional to the photocurrent that the phototransistor PTr produces in proportion to the amount of incident light and a mode in which the output signal is linearly proportional to the photocurrent. How the pixel operates in each mode will be described below. Here, the signal φVPD is a binary voltage signal that takes either a “first voltage” that is approximately equal to the direct-current voltage VPD and that is fed to the MOS transistor T1 to make it operate in a subthreshold region when the photocurrent is converted natural-logarithmically or a “second voltage” that is used as an operating point of the MOS transistor T2 when the photocurrent is converted linearly.

(1) The Mode in Which the Photocurrent is Converted Natural-Logarithmically for Output

In the circuit configured as described above, the signal φVPD is turned to the first voltage, and the signal φVPG is turned to a voltage that permits the MOS transistor T1 to operate in a subthreshold region. Then, the signal φS is turned to a low level so that, in all the individual pixels G11 to Gmn (FIG. 1) provided in the solid-state image-sensing device configured as shown in FIG. 1, the MOS transistor T5 is turned off.

In this state, the phototransistor PTr produces a photocurrent proportional to the amount of incident light, and the gate voltage of the MOS transistor T1 is logarithmically proportional to the photocurrent. Next, with identical timing, the pulse signal φS is fed to the gate of the MOS transistor T5 of the pixels G11 to Gmn. When the pulse signal φS is turned to a high level, the MOS transistor T5 is turned on. This causes the voltage that appears in the MOS transistor T1 and that is logarithmically proportional to the photocurrent to be sampled and held at the gate of the MOS transistor T2. That is, the data of an image sensed at an identical time is sampled and held in the output-stage circuit of each pixel. When this voltage is sampled and held at the gate of the MOS transistor T2, the MOS transistor T5 is turned off.

Then, the vertical scanning circuit 2 (FIG. 1) feeds the pulse signal φV to the gate of the MOS transistor T6 provided in the individual pixels G11 to Gmn sequentially to turn on the MOS transistor T6 of each pixel sequentially, and the horizontal scanning circuit 3 (FIG. 1) permits the MOS transistor Q2 to be turned on, so that an output current logarithmically proportional to the photocurrent is delivered from one pixel after another to the output signal line 6. Here, in each pixel, when the MOS transistor T6 is turned on, a current proportional to the voltage that is sampled and held at the gate of the MOS transistor T2 and that is logarithmically proportional to the photocurrent flows through the MOS transistors T2 and T6 as their drain currents and is delivered as an output current to the output signal line 6. After this signal has been read out, the MOS transistor T6 is turned off.

As described above, in this embodiment, after all the pixels of the solid-state image-sensing device have performed an image-sensing operation at an identical time, the vertical and horizontal scanning circuits control the individual pixels in such a way that the pixels sequentially output their output signals that as a whole carry the data of the image sensed at that identical time. This permits the solid-state image-sensing device to output as serial data an output signal carrying the data of an image sensed at an identical time. By obtaining an output signal as serial data in this way, it is possible to reproduce an image of which the data is free from temporal errors.

(2) The Mode in Which the Photocurrent is Converted Linearly for Output

The signal φVPD is turned to the second voltage. The signal φVPG is, as a binary voltage signal, switched between two levels so that, when it is at a high level, the MOS transistor T1 is turned on and, when it is at a low level, the MOS transistor T1 is turned off. In the linear conversion mode, where the signals φVPD and φVPG are controlled in this way, an image-sensing operation and a reset operation are achieved as described below. Here, the MOS transistor T1 functions as a resetting transistor, and the MOS transistor T2 functions as a signal amplification transistor.

(2-a) Image-Sensing Operation

First, the signal φVPG is turned to a high level so that, through the MOS transistor T1, the gate voltage of the MOS transistor T2 is reset. Then, the signal φVPG is turned to a low level to turn the MOS transistor T1 off. Moreover, the signal φS is turned to a low level so that, in all the individual pixels G11 to Gmn (FIG. 1) provided in the solid-state image-sensing device configured as shown in FIG. 1, the MOS transistor T5 is turned off.

In this state, a photocurrent flows through the phototransistor PTr, and this causes the gate voltage of the MOS transistor T2 to vary. Specifically, a current that is determined by the number of holes appearing in the phototransistor PTr is fed from the phototransistor PTr to the drain of the MOS transistor T5. Thus, the drain voltage of the MOS transistor T5 is linearly proportional to the photocurrent. Here, since the current that flows into the MOS transistor T5 through its drain is determined by the number of holes that appear in the phototransistor PTr, the more intense the incident light, the lower the drain voltage of the MOS transistor T5.

Next, with identical timing, the pulse signal φS is fed to the gate of the MOS transistor T5 of the pixels G11 to Gmn. When the pulse signal φS is turned to a high level, the MOS transistor T5 is turned on. This causes the voltage that appears at the drain of the MOS transistor T5 and that is linearly proportional to the photocurrent to be sampled and held at the gate of the MOS transistor T2. That is, the data of an image sensed at an identical time is sampled and held in the output-stage circuit of each pixel. When this voltage is sampled and held at the gate of the MOS transistor T2, the MOS transistor T5 is turned off.

Then, the vertical scanning circuit 2 (FIG. 1) feeds the pulse signal φV to the gate of the MOS transistor T6 provided in the individual pixels G11 to Gmn sequentially to turn on the MOS transistor T6 of each pixel sequentially, and the horizontal scanning circuit 3 (FIG. 1) permits the MOS transistor Q2 to be turned on, so that an output current linearly proportional to the photocurrent is delivered from one pixel after another to the output signal line 6. Here, in each pixel, when the MOS transistor T6 is turned on, a current proportional to the voltage that is sampled and held at the gate of the MOS transistor T2 and that is linearly proportional to the photocurrent flows through the MOS transistors T2 and T6 as their drain currents and is delivered as an output current to the output signal line 6. After this signal has been read out, the MOS transistor T6 is turned off.

(2-b) Reset Operation

FIG. 14 is a timing chart showing how the relevant signals are controlled when each pixel is reset. After, as described above, the pulse signal φS is fed to the gate of the MOS transistor T5 of the pixels G11 to Gmn simultaneously so that the data of an image corresponding to one frame is sampled and held and then the pulse signal φV is fed to the gate of the MOS transistor T6 of the pixels G11 to Gmn sequentially so that the output signal is read out, first, the signal φVPG is turned to a high level to turn the MOS transistor T1 on in the pixels G11 to Gmn. It is to be noted that the timing chart of FIG. 14 deals only with a reset operation that takes place within a single pixel; in reality, the pulse signal φV is fed to the gate of the MOS transistor T6 of the individual pixels G11 to Gmn sequentially in the period after the signal φS has been turned to a low level before the signal φVPG is turned to a high level.

Here, the signal φVPD fed to the drain of the MOS transistor T1 is at the second voltage, and therefore a voltage corresponding to this second voltage is applied to the drain of the MOS transistor T5. Thus, the drain voltage of the MOS transistor T5 is reset to this voltage. After this resetting, with identical timing, the pulse signal φS is fed to the gate of the MOS transistor T5 of the pixels G11 to Gmn so that this reset voltage is sampled and held at the gate of the MOS transistor T2.

When this reset voltage is sampled and held at the gate of the MOS transistor T2 of the pixels G11 to Gmn, then the signal φVPG is turned to a low level, and then the pulse signal φV is fed to the gate of the MOS transistor T6 of the pixels G11 to Gmn sequentially to turn this MOS transistor T6 on. As a result, from one pixel after another, the output current produced when the gate voltage of the MOS transistor T2 is reset is delivered to the output signal line 6 so as to be read out as serial data. After this output signal (the output current), which is to be used as compensation data, has been read out, the MOS transistors T6 is turned off. Here, the pulse signal φV is fed to the MOS transistor T6 of the individual pixels G11 to Gmn sequentially in the period after the signal φVPG has been turned to a low level before the signal φS is turned to a high level.

In this embodiment, it is advisable to store the output signals read out from the individual pixels G11 to Gmn in an image-sensing operation and in a sensitivity variation detection operation, as image data and compensation data respectively, in a memory or the like that can store at least the whole of one of those two sets of data. For example, by storing pixel-to-pixel compensation data in a memory, it is possible to correct image data with the compensation data stored in the memory and thereby eliminate pixel-to-pixel variations from the image data.

Ninth Embodiment

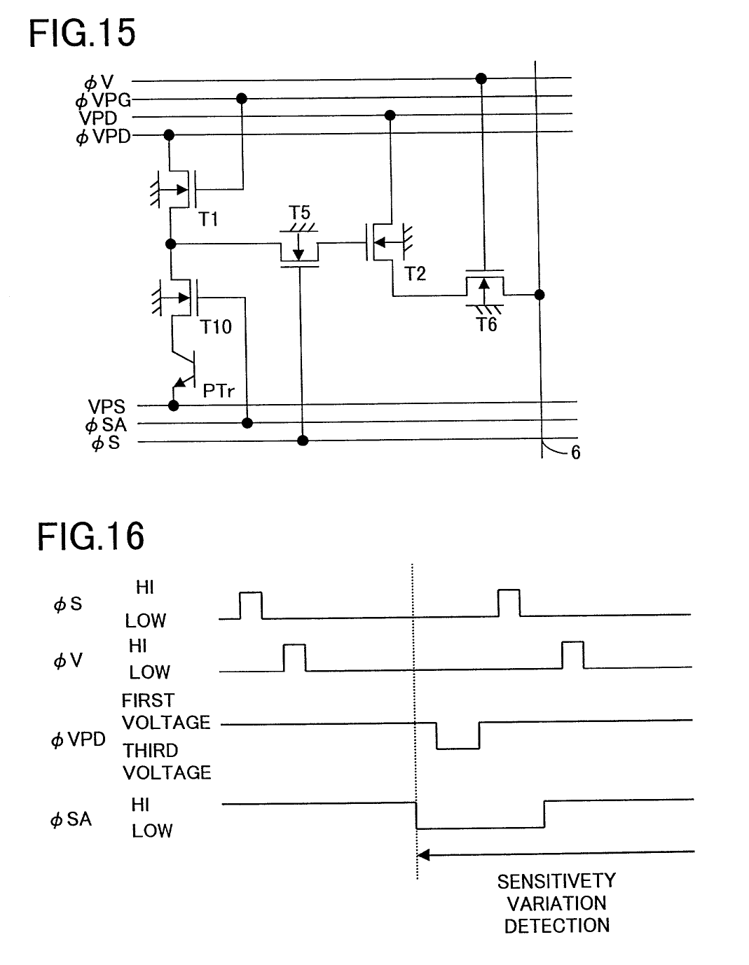

A ninth embodiment of the invention will be described below with reference to the drawings. FIG. 15 is a circuit diagram showing the configuration of each pixel provided in the solid-state image-sensing device of this embodiment. In the following description, such circuit elements, signal lines, and others as serve the same purposes as in the pixel shown in FIG. 13 are identified with the same reference numerals or symbols, and their detailed explanations will not be repeated.

As shown in FIG. 15, in this embodiment, as in the seventh embodiment (FIG. 11), a MOS transistor T10 is additionally provided that has its drain connected to the source of the MOS transistor T1 and that has its source connected to the collector of the phototransistor PTr. A signal φSA is fed to the gate of the MOS transistor T10. In other respects, the pixel of this embodiment is configured in the same manner as that of the eighth embodiment (FIG. 13).

As in the seventh embodiment, the signal φVPD is a ternary voltage signal that takes one of a “first voltage” that is approximately equal to the direct-current voltage VPD and that is fed to the MOS transistor T1 to make it operate in a subthreshold region in the logarithmic conversion mode so that the photocurrent is converted natural-logarithmically, a “second voltage” that is used as the operating point of the MOS transistor T2 when the photocurrent is converted linearly, and a “third voltage” that is approximately equal to the direct-current voltage VPS so as to permit detection of the variation in the threshold level of the MOS transistor T1 when the photocurrent is converted natural-logarithmically.

(1) The Mode in Which the Photocurrent is Converted Natural-Logarithmically for Output

(1-1) Image-Sensing Operation

The signal φVPD is turned to the first voltage so that the MOS transistor T1 operates in the subthreshold region, and the signal φSA that is fed to the gate of the MOS transistor T10 is turned to a high level to turn this MOS transistor T10 on. In this state, as in the eighth embodiment, while the MOS transistor T5 in the individual pixels G11 to Gmn is off, the phototransistor PTr produces a photocurrent proportional to the amount of incident light, and the source voltage of the MOS transistor T1 is logarithmically proportional to the photocurrent. Next, with identical timing, the pulse signal φS is fed to the gate of the MOS transistor T5 of the pixels G11 to Gmn, so that the voltage logarithmically proportional to the photocurrent is sampled and held at the gate of the MOS transistor T2. Then, the pulse signal φV is fed to the pixels G1 to Gmn sequentially to turn the MOS transistor T6 on, so that an output current logarithmically proportional to the photocurrent is delivered to the output signal line 6. After this signal (the output current) has been read, the MOS transistor T6 is turned off.

(1-b) Sensitivity Variation Detection Operation

FIG. 16 is a timing chart showing how the relevant signals are controlled when the variation in sensitivity of each pixel is detected. After, as described above, the pulse signal φS is fed to the gate of the MOS transistor T5 of the pixels G11 to Gmn simultaneously so that the data of an image corresponding to one frame is sampled and held and then the pulse signal φV is fed to the gate of the MOS transistor T6 of the pixels G11 to Gmn sequentially so that the output signal is read out, first, the signal φSA is turned to a low level to turn the MOS transistor T10 off. It is to be noted that the timing chart of FIG. 16 deals only with a reset operation that takes place within a single pixel; in reality, the pulse signal φV is fed to the gate of the MOS transistor T6 of the individual pixels G11 to Gmn sequentially in the period after the signal φS has been turned to a low level before the signal φSA is turned to a low level. Then, the signal φVPD is turned to the third voltage so that negative electric charge is accumulated between the drain and source of the MOS transistor T1. Here, the signal φS is at a low level, and the MOS transistor T5 is off.

Next, the signal φVPD is turned back to the first voltage. As a result, part of the accumulated negative electric charge flows out to the signal line of the signal φVPD, and some negative electric charge remains accumulated at the source of the MOS transistor T1. The amount of negative electric charge accumulated here is determined by the gate-to-source threshold voltage of the MOS transistor T1. When this negative electric charge is accumulated at the source of the MOS transistor T1, the pulse signal φS is fed to the gate of the MOS transistor T5 so that the source voltage of the MOS transistor T1 is sampled and held at the gate of the MOS transistor T2. It is to be noted that, for the individual pixels G11 to Gmn, the signals φSA, φS, and φVPD are each switched simultaneously.

When this voltage is sampled and held at the gate of the MOS transistor T2 of the pixels G11 to Gmn, then the pulse signal φV is fed to the gate of the MOS transistor T6 of the pixels G11 to Gmn sequentially. As a result, from one pixel after another, an output current proportional to the gate voltage of the MOS transistor T2 is delivered to the output signal line 6 so as to be read out as serial data. After this output signal (the output current), which is to be used as compensation data, has been read out, the MOS transistors T6 is turned off. Here, the pulse signal φV is fed to the MOS transistor T6 of the individual pixels G11 to Gmn sequentially in the period after the signal φSA has been turned to a high level before the signal φS is turned to a high level.

(2) The Mode in Which the Photocurrent is Converted Linearly for Output

As in the sixth embodiment, the signal φVPD is turned to the second voltage. The signal φVPG is, as a binary voltage signal, switched between two levels so that, when it is at a high level, the MOS transistor T1 is turned on and, when it is at a low level, the MOS transistor T1 is turned off. The signal φSA is kept at a high level all the time, and therefore the MOS transistor T10 that receives at its gate the signal φSA remains on all the time. Thus, the MOS transistor T1 functions as a resetting transistor, and the MOS transistor T2 functions as a signal amplification transistor.

(2-a) Image-Sensing Operation

First, the signal φVPG is turned to a high level so that, through the MOS transistor T1, the gate voltage of the MOS transistor T2 is reset. Then, the signal φVPG is turned to a low level to turn the MOS transistor T1 off. Moreover, the signal φS is turned to a low level so that, in all the individual pixels G11 to Gmn (FIG. 1) provided in the solid-state image-sensing device configured as shown in FIG. 1, the MOS transistor T5 is turned off.

In this state, as in the eighth embodiment, a photocurrent flows through the phototransistor PTr, and the drain voltage of the MOS transistor T5 is linearly proportional to the photocurrent. Next, with identical timing, the pulse signal φS is fed to the gate of the MOS transistor T5 of the pixels G11 to Gmn, so that the voltage that appears at the drain of the MOS transistor T5 and that is linearly proportional to the photocurrent is sampled and held at the gate of the MOS transistor T2.

Then, the pulse signal φV is fed to the pixels G1 to Gmn sequentially to turn the MOS transistor T6 on, so that an output current linearly proportional to the photocurrent is delivered to the output signal line 6. Here, in each pixel, when the MOS transistor T6 is turned on, a current proportional to the voltage that is sampled and held at the gate of the MOS transistor T2 and that is linearly proportional to the photocurrent flows through the MOS transistors T2 and T6 as their drain currents and is delivered as an output current to the output signal line 6. After this signal has been read, the MOS transistor T6 is turned off.

(2-b) Reset Operation

In the linear conversion mode, a reset operation is achieved by feeding in the relevant signals with the timing shown in the timing chart of FIG. 14 as in the eighth embodiment. After, as described above, the pulse signal φV is fed to the gate of the MOS transistor T6 and the output signal is read out, first, the signal φVPG is turned to a high level to turn on the MOS transistor T1 of the pixels G11 to Gmn and thereby reset the drain voltage of the MOS transistor T5. After this resetting, with identical timing, the pulse signal φS is fed to the gate of the MOS transistor T5 of the pixels G11 to Gmn, so that this reset voltage is sampled and held at the gate of the MOS transistor T2.

When this reset voltage is sampled and held at the gate of the MOS transistor T2 of the pixels G11 to Gmn, then the signal φVPG is turned to a low level, and then the pulse signal φV is fed to the pixels G11 to Gmn sequentially to turn the MOS transistor T6 on. As a result, from one pixel after another, an output current produced when the gate voltage of the MOS transistor T2 is reset is delivered to the output signal line 6. After this signal (the output current), which is to be used as compensation data, has been read out, the MOS transistor T6 is turned off.

In this embodiment, it is advisable to store the output signals read out from the individual pixels G11 to Gmn in an image-sensing operation and in a sensitivity variation detection operation, as image data and compensation data respectively, in a memory or the like that can store at least the whole of one of those two sets of data. For example, by storing pixel-to-pixel compensation data in a memory, it is possible to correct image data with the compensation data stored in the memory and thereby eliminate pixel-to-pixel variations from the image data.

Second Example of Pixel Configuration

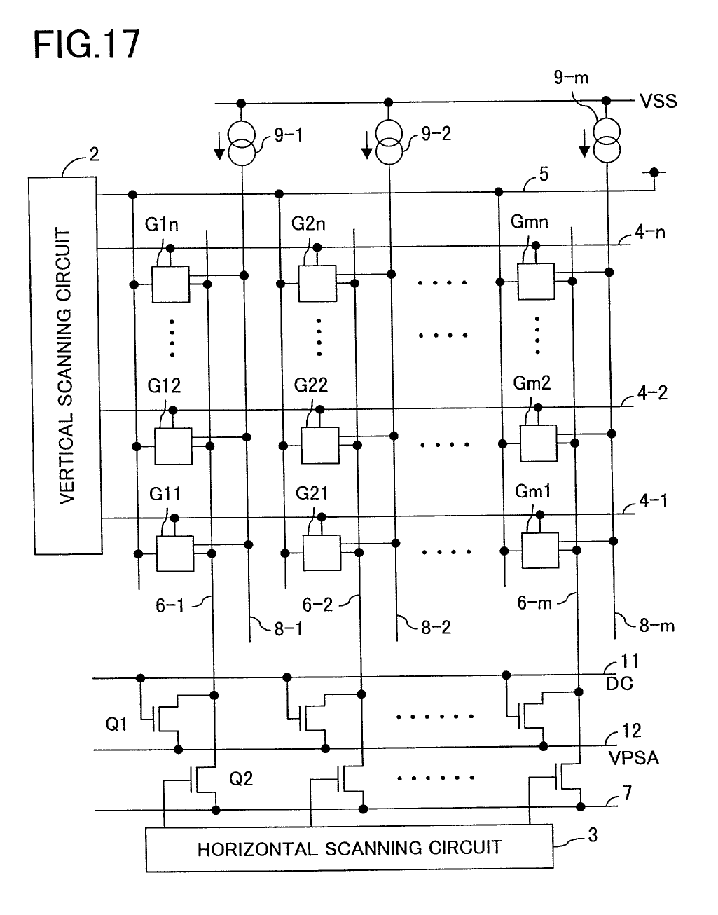

FIG. 17 schematically shows the configuration of a portion of another two-dimensional MOS-type solid-state image-sensing device embodying the invention. In the following description, such circuit elements, signal lines, and others as serve the same purposes as in the two-dimensional MOS-type solid-state image-sensing device of which the configuration of a portion is shown in FIG. 1 are identified with the same reference numerals or symbols, and their detailed explanations will not be repeated.

In the solid-state image-sensing device shown in FIG. 17, as compared with the one shown in FIG. 1, constant-current sources 9-1, 9-2, . . . , 9-m and current feed lines 8-1, 8-2, . . . , 8-m are additionally provided. The constant-current sources 9-1, 9-2, . . . , 9-m feed currents to the pixels G11 to Gln, G21 to G2n, . . . Gm1 to Gmn column by column by way of the current feed lines 8-1, 8-2, . . . , 8-m, respectively. The individual pixels are connected not only to the lines 4-1, 4-2, . . . , 4-n, to the output signal lines 6-1, 6-2, . . . , 6-m, to the current feed lines 8-1, 8-2, . . . , 8-m, and to the power line 5 mentioned above, but also to other lines (for example clock lines and bias supply lines). These other lines, however, are omitted in FIG. 17.

As shown in FIG. 17, for each of the output signal lines 6-1, 6-2, . . . , 6-m, a pair of N-channel MOS transistors Q1 and Q2 is provided. Here, a description will be given only with respect to the output signal line 6-1 as their representative. The MOS transistor Q1 has its gate connected to a direct-current voltage line 11, has its drain connected to the output signal line 6-1, and has its source connected to a line 12 of a direct-current voltage VPSA. On the other hand, the MOS transistor Q2 has its drain connected to the output signal line 6-1, has its source connected to a signal line 7 serving as a final destination line, and has its gate connected to the horizontal scanning circuit 3.

As will be described later, the pixels G11 to Gmn are each provided with an N-channel MOS transistor Ta that outputs a signal proportional to the photoelectric charge generated in each pixel. How this MOS transistor Ta is connected to the above-mentioned MOS transistor Q1 is as shown in FIG. 2A, i.e. the same as with the configuration shown in FIG. 1. The circuit shown in FIG. 2A forms an amplifier circuit of a source-follower type. This MOS transistor Ta corresponds to the MOS transistor T7 in the tenth embodiment, and corresponds to the MOS transistor T2 in the eleventh to fifteenth embodiments.

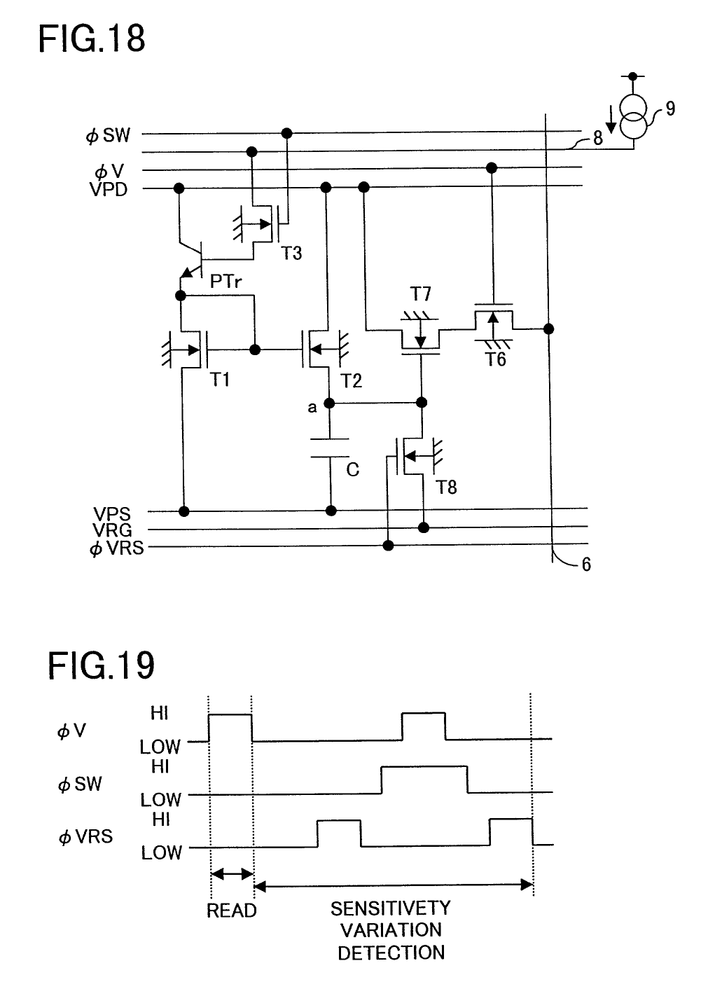

The MOS transistor Q2 is controlled by the horizontal scanning circuit 3 so as to function as a switching device. As will be described later, in all of the embodiments of the invention shown in FIG. 18 and the following figures, within each pixel, another N-channel MOS transistor T6 functioning as a switch is provided. If this MOS transistor T6 is illustrated explicitly, the circuit shown in FIG. 2A has, more precisely, a circuit configuration as shown in FIG. 2B. Specifically, the MOS transistor T6 is inserted between the MOS transistor Q1 and the MOS transistor Ta. Here, the MOS transistor T6 serves to select a row, and the MOS transistor Q2 serves to select a column. It is to be noted that the circuit configurations shown in FIGS. 17, 2A, and 2B are common to the tenth to fifteenth embodiments of the invention described hereinafter.

The circuit configuration shown in FIGS. 2A and 2B permits the signal to be output with a high gain. Accordingly, even in a case where the photocurrent generated in a photosensitive element is converted natural-logarithmically to obtain a wider dynamic range and thus the output signal obtained is comparatively low, this amplifier circuit amplifies the signal so as to make it sufficiently high and thus easier to process in the succeeding signal processing circuit (not shown). Here, the MOS transistor Q1 that serves as the load resistor of the amplifier circuit is provided within each pixel; however, such transistors may be provided, instead, one for each of the output signal lines 6-1, 6-2, . . . , 6-m to which the pixels arranged in columns are collectively connected column by column. This helps reduce the number of load resistors or constant-current sources required, and thereby reduce the area occupied by the amplifying circuits on a semiconductor chip.

Tenth Embodiment

A tenth embodiment of the invention, which is applicable to each pixel of the second example of pixel configuration shown in FIG. 17, will be described below with reference to the drawings. FIG. 18 is a circuit diagram showing the configuration of each pixel provided in the solid-state image-sensing device of this embodiment. In the following description, such circuit elements, signal lines, and others as serve the same purposes as in the pixel shown in FIG. 3 are identified with the same reference numerals or symbols, and their detailed explanations will not be repeated.

As shown in FIG. 18, in this embodiment, a MOS transistor T3 is additionally provided that has its source connected to the base of the phototransistor PTr and that has its drain connected by way of a current feed line 8 (this current feed line 8 corresponds to the current feed lines 8-1, 8-2, . . . , 8-m shown in FIG. 17) to a constant-current source 9 (this constant-current source 9 corresponds to the constant-current sources 9-1, 9-2, . . . , 9-m shown in FIG. 17). A signal φSW is fed to the gate of the MOS transistor T3. In other respects, the pixel of this embodiment is configured in the same manner as that of the first embodiment (FIG. 3). The MOS transistor T3 is, like the MOS transistor T1, an N-channel MOS transistor having its back gate grounded.

In this configuration, when an image-sensing operation is performed, the signal φSW is turned to a low level to turn the MOS transistor T3 off so that the base of the phototransistor PTr is brought into a floating state. On the other hand, when the variation in sensitivity of the pixel is detected, the signal φSW is turned to a high level to turn the MOS transistor T3 on so that a constant current is fed from the constant-current source 9 to the base of the phototransistor PTr. How an image-sensing operation and a sensitivity variation detection operation are performed will be described below.

(1) Image-Sensing Operation

First, a low level is fed as the signal φSW to the gate of the MOS transistor T3 to turn the MOS transistor T3 off so that the base of the phototransistor PTr is brought into a floating state. In this state, the phototransistor PTr, the MOS transistors T1, T2, and T6 to T8, and the capacitor C operate in the same manner as in the first embodiment so that an output current logarithmically proportional to the photocurrent is delivered to the output signal line 6.

Specifically, when light is incident on the phototransistor PTr, a photocurrent appears therein, and, due to the subthreshold characteristics of MOS transistors, a voltage natural-logarithmically proportional to the photocurrent appears at the gates of the MOS transistors T1 and T2. This voltage causes an amount of electric charge equivalent to the value obtained by natural-logarithmically converting the integral of the photocurrent is accumulated in the capacitor C. Then, the pulse signal φV is fed to the gate of the MOS transistor T6 to turn this transistor T6 on. This causes an output current natural-logarithmically proportional to the integral of the photocurrent to be delivered through the MOS transistors T6 and T7 to the output signal line 6.

(2) Sensitivity Variation Detection Operation

How the variation in sensitivity of the pixel is detected will be described below with reference to FIG. 19. After, as described above, the pulse signal φV is fed in so that the output current is fed out, first, the pulse signal φVRS is fed to the gate of the MOS transistor T8 to reset the capacitor C and the node “a”. Next, a high level is fed as the signal φSW to the gate of the MOS transistor T3 to turn this MOS transistor T3 on so that a constant current is fed from the constant-current source 9 by way of the current feed line 8 to the base of the phototransistor PTr.

When this constant current is fed from the constant-current source 9 to each pixel, the constant-current source 9 keeps the base current of the phototransistor PTr constant. Here, this base current is sufficiently higher than the current that appears in proportion to the amount of light incident on the pn junction between the base and emitter of the phototransistor PTr. Thus, the emitter current of the phototransistor PTr, namely the photocurrent, is determined by the current fed from the constant-current source 9. Accordingly, the value of the photocurrent here represents the amplification factor of the phototransistor PTr, which is the very cause of the variation in sensitivity of the pixel.

As a result, a voltage logarithmically proportional to the photocurrent that is determined by the constant-current source 9 appears at the gates of the MOS transistors T1 and T2. This voltage causes an amount of electric charge equivalent to the value obtained by natural-logarithmically converting the integral of the photocurrent is accumulated in the capacitor C. Then, the pulse signal φV is fed to the gate of the MOS transistor T6 to turn this MOS transistor T6 on, so that an output current natural-logarithmically proportional to the integral of the photocurrent is delivered through the MOS transistors T6 and T7 to the output signal line 6. Since this photocurrent represents the amplification factor of the phototransistor PTr, which is the very cause of the variation in sensitivity of the pixel, the output signal thus delivered to the output signal line 6 represents the variation in sensitivity of each pixel.

After, as described above, the pulse signal φV is fed in so that the variation in sensitivity of each pixel is detected, the signal φSW is turned to a low level to turn the MOS transistor T3 off again so that the base of the phototransistor PTr is brought into a floating state. Thereafter, the pulse signal φVRS is fed to the gate of the MOS transistor T8 to reset the capacitor C and the node “a” in preparation for the next image-sensing operation.

In this embodiment, the pixel may be, as in the second embodiment (FIG. 5), so configured that a signal φD is fed to the drain of the MOS transistor T2 and that the MOS transistor T8 is omitted. In this case, the resetting of the capacitor C and the node “a” is achieved by feeding in a low-level pulse signal as the signal φD with the same timing as the signal φVRS shown in FIG. 19.

Eleventh Embodiment

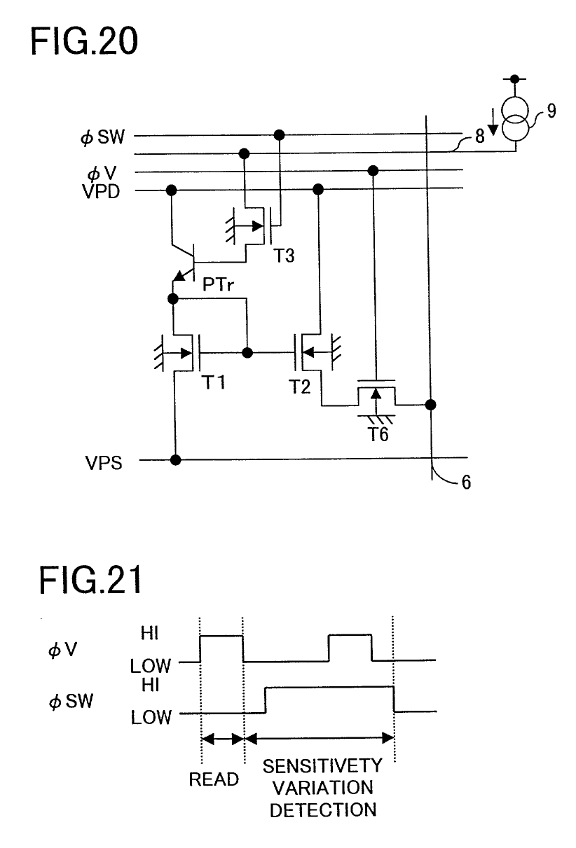

An eleventh embodiment of the invention, which is applicable to each pixel of the second example of pixel configuration shown in FIG. 17, will be described below with reference to the drawings. FIG. 20 is a circuit diagram showing the configuration of each pixel provided in the solid-state image-sensing device of this embodiment. In the following description, such circuit elements, signal lines, and others as serve the same purposes as in the pixel shown in FIG. 6 are identified with the same reference numerals or symbols, and their detailed explanations will not be repeated.

As shown in FIG. 20, in this embodiment, as in the tenth embodiment (FIG. 18), a MOS transistor T3 is additionally provided that has its source connected to the base of the phototransistor PTr and that has its drain connected by way of a current feed line 8 to a constant-current source 9. A signal φSW is fed to the gate of the MOS transistor T3. In other respects, the pixel of this embodiment is configured in the same manner as that of the third embodiment (FIG. 6). The MOS transistor T3 is, like the MOS transistor T1, an N-channel MOS transistor having its back gate grounded.

In this configuration, as in the tenth embodiment, when an image-sensing operation is performed, the signal φSW is turned to a low level to turn the MOS transistor T3 off so that the base of the phototransistor PTr is brought into a floating state. On the other hand, when the variation in sensitivity of the pixel is detected, the signal φSW is turned to a high level to turn the MOS transistor T3 on so that a constant current is fed from the constant-current source 9 to the base of the phototransistor PTr. How an image-sensing operation and a sensitivity variation detection operation are performed will be described below.

(1) Image-Sensing Operation

First, a low level is fed as the signal φSW to the gate of the MOS transistor T3 to turn the MOS transistor T3 off so that the base of the phototransistor PTr is brought into a floating state. In this state, the phototransistor PTr and the MOS transistors T1, T2, and T6 operate in the same manner as in the third embodiment so that an output current logarithmically proportional to the photocurrent is delivered to the output signal line 6.

Specifically, when light is incident on the phototransistor PTr, a photocurrent appears therein, and, due to the subthreshold characteristics of MOS transistors, a voltage natural-logarithmically proportional to the photocurrent appears at the gates of the MOS transistors T1 and T2. This voltage causes a current natural-logarithmically proportional to the photocurrent to flow through the MOS transistor T2 as its drain current. Then, the pulse signal φV is fed to the gate of the MOS transistor T6 to turn this transistor T6 on. This causes the above-mentioned drain current that is natural-logarithmically proportional to the photocurrent to be delivered through the MOS transistors T6 and T7 to the output signal line 6. After this signal (the output current) has been read out, the MOS transistor T6 is turned off.

(2) Sensitivity Variation Detection Operation

How the variation in sensitivity of the pixel is detected will be described below with reference to FIG. 21. After, as described above, the pulse signal φV is fed in so that the output current is fed out, first, a high level is fed as the signal φSW to the gate of the MOS transistor T3 to turn this MOS transistor T3 on so that a constant current is fed from the constant-current source 9 by way of the current feed line 8 to the base of the phototransistor PTr.

When this constant current is fed from the constant-current source 9 to each pixel, a photocurrent that is determined by this current fed from the constant-current source 9 flows through the phototransistor PTr. The value of the photocurrent here represents the amplification factor of the phototransistor PTr, which is the very cause of the variation in sensitivity of the pixel. Thus, a voltage logarithmically proportional to the photocurrent that is determined by the constant-current source 9 appears at the gates of the MOS transistors T1 and T2. This voltage tends to cause a current natural-logarithmically proportional to the photocurrent to flow through the MOS transistor T2 as its drain current.

Then, the pulse signal φV is fed to the gate of the MOS transistor T6 to turn this MOS transistor T6 on, so that a current natural-logarithmically proportional to the photocurrent flows through the MOS transistors T2 and T6 as their drain currents and is delivered to the output signal line 6. Since this photocurrent represents the amplification factor of the phototransistor PTr, which is the very cause of the variation in sensitivity of the pixel, the output signal thus delivered to the output signal line 6 represents the variation in sensitivity of each pixel. After, in this way, the pulse signal φV is fed in so that the variation in sensitivity of each pixel is detected, the signal φSW is turned to a low level to turn the MOS transistor T3 off again in preparation for the next image-sensing operation.

Twelfth Embodiment

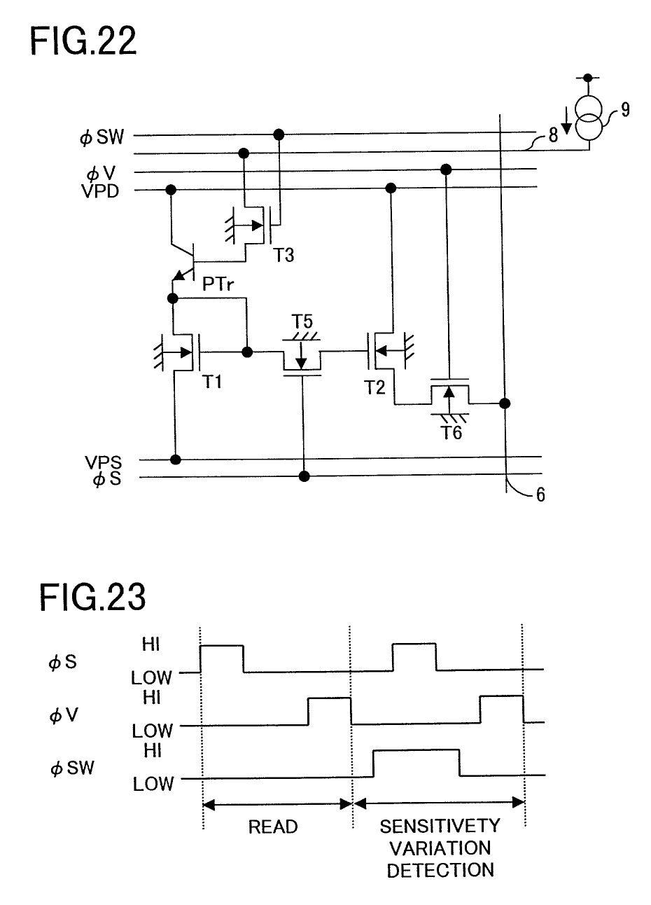

A twelfth embodiment of the invention, which is applicable to each pixel of the second example of pixel configuration shown in FIG. 17, will be described below with reference to the drawings. FIG. 22 is a circuit diagram showing the configuration of each pixel provided in the solid-state image-sensing device of this embodiment. In the following description, such circuit elements, signal lines, and others as serve the same purposes as in the pixel shown in FIG. 7 are identified with the same reference numerals or symbols, and their detailed explanations will not be repeated.

As shown in FIG. 22, in this embodiment, as in the tenth embodiment (FIG. 18), a MOS transistor T3 is additionally provided that has its source connected to the base of the phototransistor PTr and that has its drain connected by way of a current feed line 8 to a constant-current source 9. A signal φSW is fed to the gate of the MOS transistor T3. In other respects, the pixel of this embodiment is configured in the same manner as that of the fourth embodiment (FIG. 7). The MOS transistor T3 is, like the MOS transistor T1, an N-channel MOS transistor having its back gate grounded.

In this configuration, as in the tenth embodiment, when an image-sensing operation is performed, the signal φSW is turned to a low level to turn the MOS transistor T3 off so that the base of the phototransistor PTr is brought into a floating state. On the other hand, when the variation in sensitivity of the pixel is detected, the signal φSW is turned to a high level to turn the MOS transistor T3 on so that a constant current is fed from the constant-current source 9 to the base of the phototransistor PTr. How an image-sensing operation and a sensitivity variation detection operation are performed will be described below.

(1) Image-Sensing Operation

First, a low level is fed as the signal φSW to the gate of the MOS transistor T3 to turn the MOS transistor T3 off so that the base of the phototransistor PTr is brought into a floating state. In this state, the phototransistor PTr and the MOS transistors T1, T2, T5, and T6 operate in the same manner as in the fourth embodiment so that an output current logarithmically proportional to the photocurrent is delivered to the output signal line 6.

First, the signal φS is turned to a low level so that, in all the individual pixels G11 to Gmn (FIG. 17) provided in the solid-state image-sensing device configured as shown in FIG. 17, the MOS transistor T5 is turned off. In this state, the phototransistor PTr produces a photocurrent proportional to the amount of incident light, and the gate voltage of the MOS transistor T1 is logarithmically proportional to the photocurrent. Next, with identical timing, the pulse signal φS is fed to the gate of the MOS transistor T5 of the pixels G11 to Gmn. This causes the voltage that appears in the MOS transistor T1 and that is logarithmically proportional to the photocurrent to be sampled and held at the gate of the MOS transistor T2. After this voltage is sampled and held there, the MOS transistor T5 is turned off.

Then, the vertical scanning circuit 2 (FIG. 17) feeds the pulse signal φV to the gate of the MOS transistor T6 provided in the individual pixels G11 to Gmn sequentially to turn on the MOS transistor T6 of each pixel sequentially, and the horizontal scanning circuit 3 (FIG. 17) permits the MOS transistor Q2 to be turned on, so that an output current logarithmically proportional to the photocurrent that is sampled and held at the gate of the MOS transistor T3 is delivered from one pixel after another to the output signal line 6. After this signal has been read out, the MOS transistor T6 is turned off.

(2) Sensitivity Variation Detection Operation

How the variation in sensitivity of the pixel is detected will be described below with reference to FIG. 23. It is to be noted that the timing chart of FIG. 23 only illustrates how the relevant signals are controlled within a single pixel. After, as described above, the pulse signal φS is fed to all the pixels and then the pulse-signal φV is fed to the individual pixels sequentially so that an output current is output from one pixel after another, first, a high level is fed as the signal φSW to the gate of the MOS transistor T3 to turn this MOS transistor T3 on so that a constant current is fed from the constant-current source 9 by way of the current feed line 8 to the base of the phototransistor PTr.

When this constant current is fed from the constant-current source 9 to each pixel, a photocurrent that is determined by this current fed from the constant-current source 9 flows through the phototransistor PTr. The value of the photocurrent here represents the amplification factor of the phototransistor PTr, which is the very cause of the variation in sensitivity of the pixel. Thus, a voltage logarithmically proportional to the photocurrent that is determined by the constant-current source 9 appears at the gate of the MOS transistor T1.

Next, the pulse signal φS is fed to the gate of the MOS transistor T5 of all the pixels. This causes the gate voltage of the MOS transistor T1, which is determined by the constant-current source 9 and which is logarithmically proportional to the photocurrent, to be sampled and held at the gate of the MOS transistor T2. This voltage tends to cause a current natural-logarithmically proportional to the photocurrent to flow through the MOS transistor T2 as its drain current. When this voltage is sampled and held at the gate of the MOS transistor T2, the MOS transistor T5 is turned off.

Then, the signal φSW is turned to a low level to turn the MOS transistor T3 off. Thereafter, the signal φV is fed to the gate of the MOS transistor T6 of the individual pixels to turn this MOS transistor T6 on so that a current natural-logarithmically proportional to the photocurrent flows through the MOS transistors T2 and T6 as their drain current and is delivered to the output signal line 6. Since this photocurrent represents the amplification factor of the phototransistor PTr, which is the very cause of the variation in sensitivity of the pixel, the output signal thus delivered to the output signal line 6 represents the variation in sensitivity of each pixel. After, in this way, the signals that are sampled and held in the individual pixels simultaneously as representing their variations in sensitivity are output sequentially from one pixel after another as serial data, the MOS transistor T6 is turned off in preparation for the next image-sensing operation.

Thirteenth Embodiment

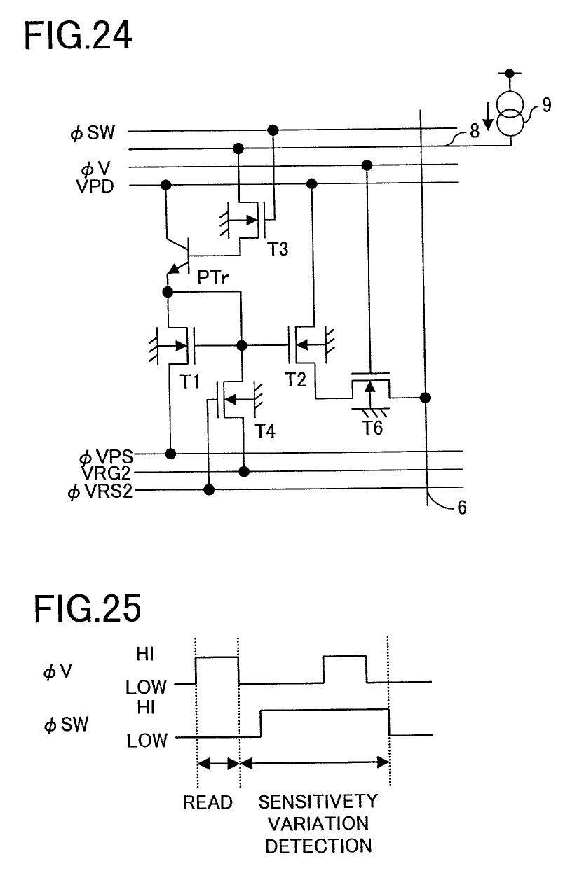

A thirteenth embodiment of the invention, which is applicable to each pixel of the second example of pixel configuration shown in FIG. 17, will be described below with reference to the drawings. FIG. 24 is a circuit diagram showing the configuration of each pixel provided in the solid-state image-sensing device of this embodiment. In the following description, such circuit elements, signal lines, and others as serve the same purposes as in the pixel shown in FIG. 8 are identified with the same reference numerals or symbols, and their detailed explanations will not be repeated.

As shown in FIG. 24, in this embodiment, as in the tenth embodiment (FIG. 18), a MOS transistor T3 is additionally provided that has its source connected to the base of the phototransistor PTr and that has its drain connected by way of a current feed line 8 to a constant-current source 9. A signal φSW is fed to the gate of the MOS transistor T3. In other respects, the pixel of this embodiment is configured in the same manner as that of the fifth embodiment (FIG. 8). The MOS transistor T3 is, like the MOS transistors T1, T2, T4, and T6, an N-channel MOS transistor having its back gate grounded. Here, the signal φVPS is a binary signal that is either at a high level that permits the MOS transistors T1 and T2 to operate in a subthreshold region or at a low level that is approximately equal to the direct-current voltage VPD. How the pixel operates in each mode will be described below.

(1) The Mode in Which the Photocurrent is Converted Natural-Logarithmically for Output

(1-a) Image-Sensing Operation

First, a low level is fed as the signal φSW to the gate of the MOS transistor T3 to turn the MOS transistor T3 off so that the base of the phototransistor PTr is brought into a floating state. In this state, the phototransistor PTr and the MOS transistors T1, T2, T4, and T6 operate in the same manner as in the fifth embodiment so that an output current logarithmically proportional to the photocurrent is delivered to the output signal line 6.

Specifically, first, the signal φVPS is turned to a low level so that the MOS transistors T1 and T2 are so biased as to operate in a subthreshold region, and the signal φVRS2 is turned to a low level to turn the MOS transistor T4 off. In this state, when light is incident on the phototransistor PTr, a photocurrent appears therein, and, due to the subthreshold characteristics of MOS transistors, a voltage natural-logarithmically proportional to the photocurrent appears at the gates of the MOS transistors T1 and T2. This voltage tends to cause a current equivalent to the value obtained by natural-logarithmically converting the photocurrent to flow through the MOS transistor T2.

Next, the pulse signal φV is fed to the gate of the MOS transistor T6 to turn this MOS transistor T6 on. As a result, a current proportional to the voltage at the gate of the MOS transistor T2 flows through the MOS transistors T2 and T6 as their drain currents and is delivered to the output signal line 6. The current thus delivered to the output signal line 6 is natural-logarithmically proportional to the integral of the photocurrent. After this signal (the output current) proportional to the logarithm of the amount of incident light has been read out, the MOS transistor T6 is turned off.

(1-b) Sensitivity Variation Detection Operation

How the variation in sensitivity of the pixel is detected will be described below with reference to FIG. 25. After, as described above, the pulse signal φV is fed in so that an output current is fed out, first, a high level is fed as the signal φSW to the gate of the MOS transistor T3 to turn this MOS transistor T3 on so that a constant current is fed from the constant-current source 9 by way of the current feed line 8 to the base of the phototransistor PTr.

When this constant current is fed from the constant-current source 9 to each pixel, a photocurrent that is determined by this current fed from the constant-current source 9 flows through the phototransistor PTr. The value of the photocurrent here represents the amplification factor of the phototransistor PTr, which is the very cause of the variation in sensitivity of the pixel. Thus, a voltage logarithmically proportional to the photocurrent that is determined by the constant-current source 9 appears at the gates of the MOS transistors T1 and T2. This voltage tends to cause a current natural-logarithmically proportional to the photocurrent to flow through the MOS transistor T2 as its drain current.

Then, the signal φV is fed to the gate of the MOS transistor T6 to turn this MOS transistor T6 on so that a current natural-logarithmically proportional to the photocurrent flows through the MOS transistors T2 and T6 as their drain currents and is delivered to the output signal line 6. Since this photocurrent represents the amplification factor of the phototransistor PTr, which is the very cause of the variation in sensitivity of the pixel, the output signal thus delivered to the output signal line 6 represents the variation in sensitivity of each pixel. After, in this way, the pulse signal φV is fed in so that the variation in sensitivity of each pixel is detected, the signal φSW is turned to a low level to turn the MOS transistors T3 off again in preparation for the next image-sensing operation. Here, the MOS transistor T4 is off.

(2) The Mode in Which the Photocurrent is Converted Linearly for Output

(2-a) Im ge-Sensing Operation

First, a low level is fed as the signal φSW to the gate of the MOS transistor T3 to turn the MOS transistor T3 off so that the base of the phototransistor PTr is brought into a floating state. In this state, the phototransistor PTr and the MOS transistors T1, T2, T4, and T6 operate in the same manner as in the fifth embodiment so that an output current linearly proportional to the photocurrent is delivered to the output signal line 6.

Specifically, first, the signal φVPS is turned to a high level so that the MOS transistor T1 is brought into a cut-off state, and a low level is fed as the signal φVRS2 to the gate of the MOS transistor T4 to turn this MOS transistor T4 off. In this state, when light is incident on the phototransistor PTr and a photocurrent appears therein, electric charge resulting from the photocurrent is accumulated at the gate, drain, and other portions of the MOS transistor T1, and thus the gate voltage of the MOS transistors T1 and T2 is proportional to the integral of the photocurrent.

Next, the pulse signal φV is fed to the gate of the MOS transistor T6 to turn the MOS transistor T6 on. As a result, a current proportional to the voltage at the gate of the MOS transistor T2 flows through the MOS transistors T2 and T6 as their drain currents and is delivered to the output signal line 6. In this way, it is possible to read out a signal (the output current) proportional to the amount of incident light. After this signal has been read out, the MOS transistor T6 is turned off.

(2-b) Sensitivity Variation Detection Operation

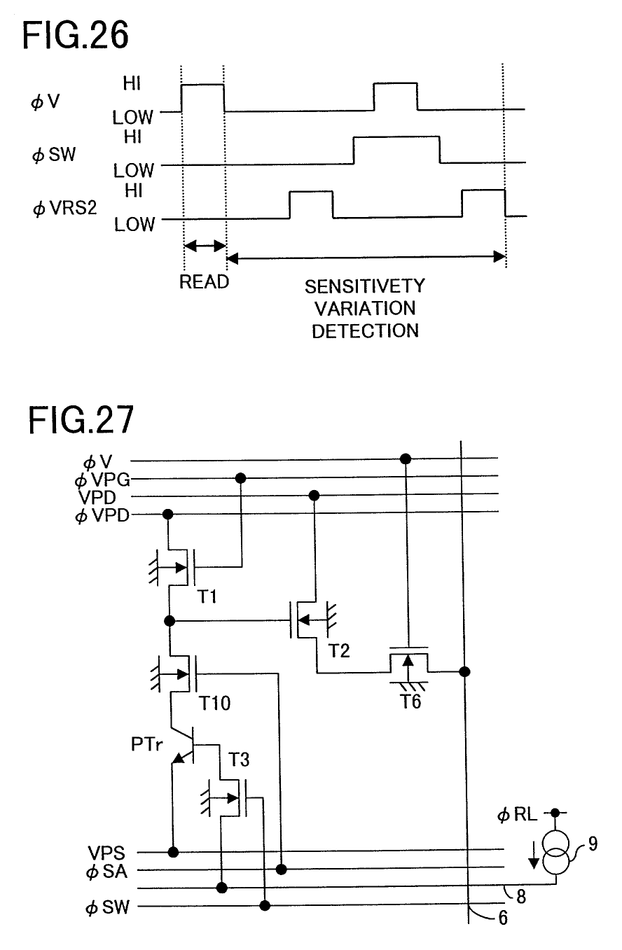

How the variation in sensitivity of the pixel is detected will be described below with reference to FIG. 26. After, as described above, the pulse signal φV is fed in so that an output current is fed out, first, the pulse signal φVRS2 is fed in to turn the MOS transistor T4 on and thereby reset the MOS transistor T1 and other circuit elements. Then, a high level is fed as the signal φSW to the gate of the MOS transistor T3 to turn this MOS transistor T3 on so that a constant current is fed from the constant-current source 9 by way of the current feed line 8 to the base of the phototransistor PTr.

When this constant current is fed from the constant-current source 9 to each pixel, a photocurrent that is determined by this current fed from the constant-current source 9 flows through the phototransistor PTr. The value of the photocurrent here represents the amplification factor of the phototransistor PTr, which is the very cause of the variation in sensitivity of the pixel. Thus, a voltage linearly proportional to the photocurrent that is determined by the constant-current source 9 appears at the gates of the MOS transistors T1 and T2. This voltage tends to cause a current linearly proportional to the photocurrent to flow through the MOS transistor T2 as its drain current.

Then, the signal φV is fed to the gate of the MOS transistor T6 to turn this MOS transistor T6 on so that a current linearly proportional to the photocurrent flows through the MOS transistors T2 and T6 as their drain currents and is delivered to the output signal line 6. Since this photocurrent represents the amplification factor of the phototransistor PTr, which is the very cause of the variation in sensitivity of the pixel, the output signal thus delivered to the output signal line 6 represents the variation in sensitivity of each pixel.

After, in this way, the pulse signal φV is fed in so that the variation in sensitivity of each pixel is detected, the signal φSW is turned to a low level to turn the MOS transistors T3 off again. Thereafter, the pulse signal φVRS2 is fed in to reset the MOS transistor T1 and other circuit elements in preparation for the next image-sensing operation. In this embodiment, the pixel may be so configured as to include, as in the first or second embodiment, a capacitor C (see FIG. 3 or 5) having one end connected to the source of the MOS transistor T2 and a MOS transistor T7 (see FIG. 3 or 5) having its gate connected to the source of the MOS transistor T2 and having its source connected to the drain of the MOS transistor T6 so that the pixel includes an integrator circuit in the output stage. Alternatively, in this embodiment, the pixel may be so configured as to include, as in the fourth embodiment, a MOS transistor T5 (see FIG. 7) having its source connected to the node between the gate and drain of the MOS transistor T1 and having its drain connected to the gate of the MOS transistor T2.

Fourteenth Embodiment

A fourteenth embodiment of the invention will be described below with reference to the drawings. FIG. 27 is a circuit diagram showing the configuration of each pixel provided in the solid-state image-sensing device of this embodiment. In the following description, such circuit elements, signal lines, and others as serve the same purposes as in the pixel shown in FIG. 11 are identified with the same reference numerals or symbols, and their detailed explanations will not be repeated.

As shown in FIG. 27, in this embodiment, a MOS transistor T3 is additionally provided that has its drain connected by way of a current feed line 8 (this current feed line 8 corresponds to the current feed lines 8-1, 8-2, . . . , 8-m shown in FIG. 17) to a constant-current source 9 (this constant-current source 9 corresponds to the constant-current sources 9-1, 9-2, . . . , 9-m shown in FIG. 17) and that has its source connected to the base of the phototransistor PTr. A signal φSW is fed to the gate of the MOS transistor T3. In other respects, the pixel of this embodiment is configured in the same manner as that of the seventh embodiment (FIG. 11). The MOS transistor T3 is an N-channel MOS transistor having its back gate grounded.

Moreover, a signal φRL is fed to the constant-current source 9. This signal φRL is a binary signal that takes either a “fourth voltage” that is lower than the voltage VPS and that brings the phototransistor PTr into a non-forward-biased state or a “fifth voltage” that is slightly higher than the voltage VPS and that brings the phototransistor PTr into a nearly-forward-biased state.

Furthermore, as in the seventh embodiment, the signal φVPD is a ternary voltage signal that takes one of a “first voltage” that is approximately equal to the direct-current voltage VPD and that is fed to the MOS transistor T1 to make it operate in a subthreshold region in the logarithmic conversion mode so that the photocurrent is converted natural-logarithmically, a “second voltage” that is used as the operating point of the MOS transistor T2 when the photocurrent is converted linearly, and a “third voltage” that is approximately equal to the direct-current voltage VPS so as to permit detection of the variation in the threshold level of the MOS transistor T1 when the photocurrent is converted natural-logarithmically.

1. When the Signal φRL is Kept at the Fourth Voltage

Under this condition, by keeping the signal φSW at a high level all the time to keep the MOS transistor T3 on, the phototransistor PTr receives a bias different from a forward bias, for example, a reverse bias, and therefore it does not function as a transistor; that is, the NP junction between its collector and base functions as a photodiode. Thus, the phototransistor PTr is brought into a state equivalent to a photodiode having its anode connected to the source of the MOS transistor T10. Operating in a state equivalent to a photodiode in this way, the phototransistor PTr produces a photocurrent at a different amplification factor than in the sixth to ninth embodiments.

(1) The Mode in Which the Photocurrent is Converted Natural-Logarithmically for Output

(1-a) Image-Sensing Operation

As in the seventh embodiment, the signal φVPD is turned to the first voltage so that the MOS transistor T2 operates in the subthreshold region, and the signal φSA is turned to a high level to turn the MOS transistor T10 on. In this state, as in the seventh embodiment, when light is incident on the phototransistor PTr, a photocurrent appears therein, and, due to the subthreshold characteristics of a MOS transistor, a voltage natural-logarithmically proportional to the photocurrent appears at the source of the MOS transistor T1 and thus at the gate of the MOS transistor T2.

Next, the signal φV is turned to a high level to turn the MOS transistor T6 on. Here, since the gate voltage of the MOS transistor T2 is logarithmically proportional to the amount of the incident light, a current natural-logarithmically proportional to the photocurrent is delivered through the MOS transistors T2 and T6 to the output signal line 6. After this signal (the output current) logarithmically proportional to the amount of incident light has been read out, the signal φV is turned to a low level to turn the MOS transistor T6 off.

(1-b) Sensitivity Variation Detection Operation

As in the seventh embodiment, the variation in sensitivity of each pixel is detected by feeding in the relevant signals with the timing shown in the timing chart of FIG. 12. After, as described above, the pulse signal φV is fed to the gate of the MOS transistor T6 and the output signal is read out, first, the signal φSA is turned to a low level to turn the MOS transistor T10 off. Then, the signal φVPD is turned to the third voltage so that negative electric charge is accumulated between the drain and source of the MOS transistor T1.

Next, the signal φVPD is turned back to the first voltage. As a result, negative electric charge of which the amount is determined by the gate-to-source threshold voltage of the MOS transistor T1 is accumulated at the source of the MOS transistor T1. Then, the pulse signal φV is fed to the gate of the MOS transistor T6 so that an output signal is read out. The output signal thus read out is proportional to the threshold voltage of the MOS transistor T1, and thus permits detection of the variation in sensitivity of each pixel. Lastly, in preparation for the next image-sensing operation, the signal φSA is turned to a high level to turn the MOS transistor T10 on.

(2) The Mode in Which the Photocurrent is Converted Linearly for Output

As in the seventh embodiment, the signal φVPD is turned to the second voltage. The signal φVPG is, as a binary voltage signal, switched between two levels so that, when it is at a high level, the MOS transistor T1 is turned on and, when it is at a low level, the MOS transistor T1 is turned off. The signal φSA is kept at a high level all the time, and therefore the MOS transistor T10 that receives at its gate the signal φSA remains on all the time. Thus, the MOS transistor T1 functions as a resetting transistor, and the MOS transistor T2 functions as a signal amplification transistor.

(2-a) Image-Sensing Operation

First, the signal φVPG is turned to a high level so that, through the MOS transistor T1, the gate voltage of the MOS transistor T2 is reset. Then, the signal φVPG is turned to a low level to turn the MOS transistor T1 off. In this state, as in the seventh embodiment, a photocurrent flows through the phototransistor PTr, and the gate voltage of the MOS transistor T2 is linearly proportional to the photocurrent.

Next, the signal φV is turned to a high level to turn the MOS transistor T6 on. Here, since the gate voltage of the MOS transistor T2 is proportional to the integral of the amount of incident light, a current linearly proportional to the photocurrent is delivered through the MOS transistors T2 and T6 to the output signal line 6. After this signal (the output current) has been read out, the MOS transistor T6 is turned off.

(2-b) Reset Operation

In the linear conversion mode, a reset operation is achieved, as in the seventh embodiment, by feeding in the relevant signals with the timing shown in the timing chart of FIG. 10. After, as described above, the pulse signal φV is fed to the gate of the MOS transistor T6 and the output signal is read out, first, the pulse signal φVPG is fed to the MOS transistor T1 to reset the gate voltage of the MOS transistor T2. Next, the pulse signal φV is fed to the gate of the MOS transistor T6, so that the output current produced when the gate voltage of the MOS transistor T2 is reset is delivered to the output signal line 6. After this signal (the output current), which is to be used as compensation data, has been read out, the MOS transistor T6 is turned off in preparation for the next image-sensing operation.

2. When the Signal φRL is Kept at the Fifth Voltage

Under this condition, when the signal φSW is turned to a high level and thereby the MOS transistor T3 is turned on, the phototransistor PTr receives a forward bias, and thus a current proportional to the current fed from the constant-current source 9 flows through the phototransistor PTr. The signal φSA is kept at a high level all the time to keep the MOS transistor T10 on.

(1) The Mode in Which the Photocurrent is Converted Natural-Logarithmically for Output

(1-a) Image-Sensing Operation

First, a low level is fed as the signal φSW to the gate of the MOS transistor T3 to turn this MOS transistor T3 off so that the base of the phototransistor PTr is brought into a floating state, and the signal φVPD is turned to the first voltage so that the MOS transistor T1 operates in a subthreshold region. In this state, as under the condition 1. described above, when light is incident on the phototransistor PTr, a photocurrent appears therein, and, due to the subthreshold characteristics of a MOS transistor, a voltage natural-logarithmically proportional to the photocurrent appears at the source of the MOS transistor T1 and thus at the gate of the MOS transistor T2.

Next, the signal φV is turned to a high level to turn the MOS transistor T6 on. Here, since the gate voltage of the MOS transistor T2 is logarithmically proportional to the amount of the incident light, a current natural-logarithmically proportional to the photocurrent is delivered through the MOS transistors T2 and T6 to the output signal line 6. After this signal (the output current) logarithmically proportional to the amount of incident light has been read out, the signal φV is turned to a low level to turn the MOS transistor T6 off.

(1-b) Sensitivity Variation Detection Operation

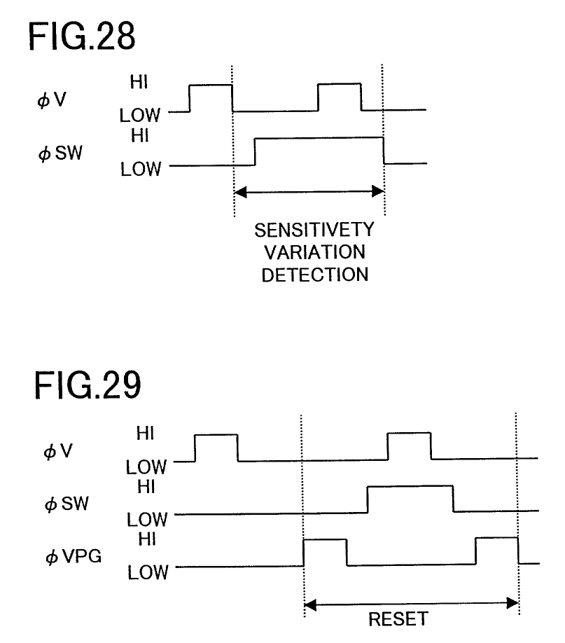

How the variation in sensitivity of the pixel is detected will be described below with reference to FIG. 28. After, as described above, the pulse signal φV is fed in so that an output current is fed out, first, a high level is fed as the signal φSW to the gate of the MOS transistor T3 to turn this MOS transistor T3 on so that a constant current is fed from the constant-current source 9 by way of the current feed line 8 to the base of the phototransistor PTr.

When this constant current is fed from the constant-current source 9 to each pixel, a photocurrent that is determined by this current fed from the constant-current source 9 flows through the phototransistor PTr. The value of the photocurrent here represents the amplification factor of the phototransistor PTr, which is the very cause of the variation in sensitivity of the pixel. Thus, a voltage logarithmically proportional to the photocurrent that is determined by the constant-current source 9 appears at the source of the MOS transistors T1 and thus at the gate of the MOS transistor T2. This voltage tends to cause a current natural-logarithmically proportional to the photocurrent to flow through the MOS transistor T2 as its drain current.

Then, the signal φV is fed to the gate of the MOS transistor T6 to turn this MOS transistor T6 on, so that a current natural-logarithmically proportional to the photocurrent flows through the MOS transistors T2 and T6 as their drain currents and is delivered to the output signal line 6. Since this photocurrent represents the amplification factor of the phototransistor PTr, which is the very cause of the variation in sensitivity of the pixel, the output signal thus delivered to the output signal line 6 represents the variation in sensitivity of each pixel. After, in this way, the pulse signal φV is fed in so that the variation in sensitivity of each pixel is detected, the signal φSW is turned to a low level to turn the MOS transistors T3 off again in preparation for the next image-sensing operation.

(2) The Mode in Which the Photocurrent is Converted Linearly for Output

As under the condition 1. described above, the signal φVPD is turned to the second voltage. The signal φVPG is, as a binary voltage signal, switched between two levels so that, when it is at a high level, the MOS transistor T1 is turned on and, when it is at a low level, the MOS transistor T1 is turned off. The MOS transistor T1 functions as a resetting transistor, and the MOS transistor T2 functions as a signal amplification transistor.

(2-a) Image-Sensing Operation

First, a low level is fed as the signal φSW to the gate of the MOS transistor T3 to turn this MOS transistor T3 off so that the base of the phototransistor PTr is brought into a floating state. Then, the signal φVPG is turned to a high level so that, through the MOS transistor T1, the gate voltage of the MOS transistor T2 is reset. Then, the signal φVPG is turned to a low level to turn the MOS transistor T1 off. In this state, a photocurrent flows through the phototransistor PTr, and the gate voltage of the MOS transistor T2 is linearly proportional to the photocurrent.

Next, the signal φV is turned to a high level to turn the MOS transistor T6 on. Here, since the gate voltage of the MOS transistor T2 is proportional to the integral of the amount of incident light, a current linearly proportional to the photocurrent is delivered through the MOS transistors T2 and T6 to the output signal line 6. After this signal (the output current) proportional to the amount of incident light has been read out, the MOS transistor T6 is turned off.

(2-b) Reset Operation

How the variation in sensitivity of the pixel is detected will be described below with reference to FIG. 29. After, as described above, the pulse signal φV is fed in so that an output current is fed out, first, the pulse signal φVPG is fed in to turn the MOS transistor T1 on and thereby reset the gate voltage of the MOS transistor T2. Then, a high level is fed as the signal φSW to the gate of the MOS transistor T3 to turn this MOS transistor T3 on so that a constant current is fed from the constant-current source 9 by way of the current feed line 8 to the base of the phototransistor PTr.

When this constant current is fed from the constant-current source 9 to each pixel, a photocurrent that is determined by this current fed from the constant-current source 9 flows through the phototransistor PTr. The value of the photocurrent here represents the amplification factor of the phototransistor PTr, which is the very cause of the variation in sensitivity of the pixel. Thus, a voltage linearly proportional to the photocurrent that is determined by the constant-current source 9 appears at the gate of the MOS transistor T2. This voltage tends to cause a current linearly proportional to the photocurrent to flow through the MOS transistor T2 as its drain current.

Then, the signal φV is fed to the gate of the MOS transistor T6 to turn this MOS transistor T6 on, so that a current linearly proportional to the photocurrent flows through the MOS transistors T2 and T6 as their drain currents and is delivered to the output signal line 6. Since this photocurrent represents the amplification factor of the phototransistor PTr, which is the very cause of the variation in sensitivity of the pixel, the output signal thus delivered to the output signal line 6 represents the variation in sensitivity of each pixel.

After, in this way, the pulse signal φV is fed in so that the variation in sensitivity of each pixel is detected, the signal φSW is turned to a low level to turn the MOS transistors T3 off again. Thereafter, the pulse signal φVPG is fed to the MOS transistor T1 to reset the gate voltage of the MOS transistor T2 in preparation for the next image-sensing operation.

Fifteenth Embodiment

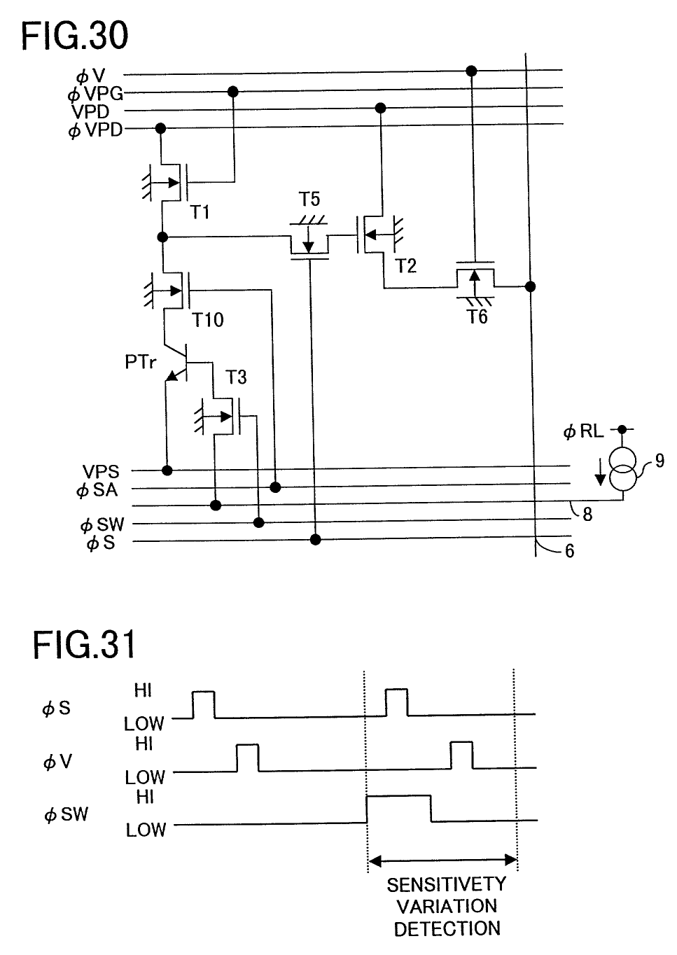

A fifteenth embodiment of the invention will be described below with reference to the drawings. FIG. 30 is a circuit diagram showing the configuration of each pixel provided in the solid-state image-sensing device of this embodiment. In the following description, such circuit elements, signal lines, and others as serve the same purposes as in the pixel shown in FIG. 27 are identified with the same reference numerals or symbols, and their detailed explanations will not be repeated.

As shown in FIG. 30, in this embodiment, as in the ninth embodiment (FIG. 15), a MOS transistor T5 is additionally provided that has its drain connected to the source of the MOS transistor T1 and that has its source connected to the gate of the MOS transistor T2. A signal φS is fed to the gate of this MOS transistor T5. In other respects, the pixel of this embodiment is configured in the same manner as that of the fourteenth embodiment (FIG. 27).

Moreover, a signal φRL is fed to the constant-current source 9. This signal φRL is a binary signal that takes either a “fourth voltage” that is lower than the voltage VPS and that brings the phototransistor PTr into a non-forward-biased state or a “fifth voltage” that is slightly higher than the voltage VPS and that brings the phototransistor PTr into a nearly-forward-biased state.

Furthermore, as in the ninth embodiment, the signal φVPD is a ternary voltage signal that takes one of a “first voltage” that is approximately equal to the direct-current voltage VPD and that is fed to the MOS transistor T1 to make it operate in a subthreshold region in the logarithmic conversion mode so that the photocurrent is converted natural-logarithmically, a “second voltage” that is used as the operating point of the MOS transistor T2 when the photocurrent is converted linearly, and a “third voltage” that is approximately equal to the direct-current voltage VPS so as to permit detection of the variation in the threshold level of the MOS transistor T1 when the photocurrent is converted natural-logarithmically.

1. When the Signal φRL is Kept at the Fourth Voltage

Under this condition, as in the fourteenth embodiment, by keeping the signal φSW at a high level all the time to keep the MOS transistor T3 on, the phototransistor PTr receives a bias different from a forward bias, for example, a reverse bias, and therefore the NP junction between its collector and base functions as a photodiode. Thus, the phototransistor PTr is brought into a state equivalent to a photodiode having its anode connected to the source of the MOS transistor T10. Operating in a state equivalent to a photodiode in this way, the phototransistor PTr produces a photocurrent at a different amplification factor than in the sixth to ninth embodiments.

(1) The Mode in Which the Photocurrent is Converted Natural-Logarithmically for Output

(1-a) Image-Sensing Operation

The signal φVPD is turned to the first voltage so that the MOS transistor T1 operates in a subthreshold region, and the signal φSA fed to the gate of the MOS transistor T10 is turned to a high level to turn this MOS transistor T10 on. In this state, as in the ninth embodiment, first, while the MOS transistor T5 in the individual pixels G11 to Gmn is off, the phototransistor PTr produces a photocurrent proportional to the amount of incident light, and the source voltage of the MOS transistor T1 is logarithmically proportional to the photocurrent.

Next, with identical timing, the pulse signal φS is fed to the gate of the MOS transistor T5 of the pixels G11 to Gmn, so that the voltage logarithmically proportional to the photocurrent is sampled and held at the gate of the MOS transistor T2. Then, the pulse signal φV is fed to the pixels G1 to Gmn sequentially to turn the MOS transistor T6 on, so that an output current logarithmically proportional to the photocurrent is delivered to the output signal line 6. After this signal (the output current) has been read out, the MOS transistor T6 is turned off.

(1-b) Sensitivity Variation Detection Operation

As in the ninth embodiment, the variation in sensitivity of each pixel is detected by feeding in the relevant signals with the timing shown in the timing chart of FIG. 16. After, as described above, the pulse signal φS is fed to the gate of the MOS transistor T5 of the pixels G11 to Gmn simultaneously so that the data of an image corresponding to one frame is sampled and held and then the pulse signal φV is fed to the gate of the MOS transistor T6 of the pixels G11 to Gmn sequentially so that the output signal is read out, first, the signal φSA is turned to a low level to turn the MOS transistor T10 off. It is to be noted that, here, the pulse signal φV is fed to the gate of the MOS transistor T6 of the individual pixels G11 to Gmn sequentially in the period after the signal φS has been turned to a low level before the signal φSA is turned to a low level. Then, the signal φVPD is turned to the third voltage so that negative electric charge is accumulated between the drain and source of the MOS transistor T1. Here, the signal φS is at a low level, and the MOS transistor T5 is off.

Next, the signal φVPD is turned back to the first voltage. As a result, negative electric charge of which the amount is determined by the gate-to-source threshold voltage of the MOS transistor T1 is accumulated at the source of the MOS transistor T1. When this negative electric charge is accumulated at the source of the MOS transistor T1, the pulse signal φS is fed to the gate of the MOS transistor T5 so that the source voltage of the MOS transistor T1 is sampled and held at the gate of the MOS transistor T2. It is to be noted that, for the individual pixels G11 to Gmn, the signals φSA, φS, and φVPD are each switched simultaneously.

When this voltage is sampled and held at the gate of the MOS transistor T2 of the pixels G11 to Gmn, then the pulse signal φV is fed to the gate of the MOS transistor T6 of the pixels G11 to Gmn sequentially. As a result, from one pixel after another, an output current proportional to the gate voltage of the MOS transistor T2 is delivered to the output signal line 6 so as to be read out as serial data. After this output signal (the output current), which is to be used as compensation data, has been read out, the MOS transistors T6 is turned off. Here, the pulse signal φV is fed to the MOS transistor T6 of the individual pixels G11 to Gmn sequentially in the period after the signal φSA has been turned to a high level before the signal φS is turned to a high level.

(2) The Mode in Which the Photocurrent is Converted Linearly for Output

As in the ninth embodiment, the signal φVPD is turned to the second voltage. The signal φVPG is, as a binary voltage signal, switched between two levels so that, when it is at a high level, the MOS transistor T1 is turned on and, when it is at a low level, the MOS transistor T1 is turned off. The signal φSA is kept at a high level all the time, and therefore the MOS transistor T10 that receives at its gate the signal φSA remains on all the time. Thus, the MOS transistor T1 functions as a resetting transistor, and the MOS transistor T2 functions as a signal amplification transistor.

(2-a) Image-Sensing Operation

First, the signal φVPG is turned to a high level so that, through the MOS transistor T1, the drain voltage of the MOS transistor T5 is reset. Then, the signal φVPG is turned to a low level to turn the MOS transistor T1 off. Then, the signal φVPG is turned to a low level to turn the MOS transistor T1 off. Moreover, the signal φS is turned to a low level so that, in all the individual pixels G11 to Gmn (FIG. 17) provided in the solid-state image-sensing device configured as shown in FIG. 17, the MOS transistor T5 is turned off.

In this state, as in the ninth embodiment, a photocurrent flows through the phototransistor PTr, and the drain voltage of the MOS transistor T5 is linearly proportional to the photocurrent. Next, with identical timing, the pulse signal φS is fed to the gate of the MOS transistor T5 of the pixels G11 to Gmn, so that the voltage that appears at the drain of the MOS transistor T5 and that is linearly proportional to the photocurrent is sampled and held at the gate of the MOS transistor T2.

Then, the pulse signal φV is fed to the pixels G1 to Gmn sequentially to turn the MOS transistor T6 on, so that an output current linearly proportional to the photocurrent is delivered to the output signal line 6. Here, in each pixel, when the MOS transistor T6 is turned on, a current proportional to the voltage that is sampled and held at the gate of the MOS transistor T2 and that is linearly proportional to the photocurrent flows through the MOS transistors T2 and T6 as their drain currents and is delivered as an output current to the output signal line 6. After this signal has been read out, the MOS transistor T6 is turned off.

(2-b) Reset Operation

In the linear conversion mode, a reset operation is achieved, as in the ninth embodiment, by feeding in the relevant signals with the timing shown in the timing chart of FIG. 14. After, as described above, the pulse signal φV is fed to the gate of the MOS transistor T6 and the output signal is read out, first, a high level is fed in as the signal φVPG to reset the drain voltage of the MOS transistor T5 of the pixels G11 to Gmn. After this resetting, with identical timing, the pulse signal φS is fed to the gate of the MOS transistor T5 of the pixels G11 to Gmn, so that this reset voltage is sampled and held at the gate of the MOS transistor T2.

When this reset voltage is sampled and held at the gate of the MOS transistor T2 of the pixels G11 to Gmn, then the signal φVPG is turned to a low level, and then the pulse signal φV is fed to the pixels G11 to Gmn sequentially to turn the MOS transistor T6 on. As a result, from one pixel after another, an output current produced when the gate voltage of the MOS transistor T2 is reset is delivered to the output signal line 6. After this signal (the output current), which is to be used as compensation data, has been read out, the MOS transistor T6 is turned off.

2. When the Signal φRL is Kept at the Fifth Voltage

Under this condition, when the signal φSW is turned to a high level and thereby the MOS transistor T3 is turned on, the phototransistor PTr receives a forward bias, and thus a current proportional to the current fed from the constant-current source 9 flows through the phototransistor PTr. The signal φSA is kept at a high level all the time to keep the MOS transistor T10 on.

(1) The Mode in Which the Photocurrent is Converted Natural-Logarithmically for Output

(1-a) Image-Sensing Operation

First, a low level is fed as the signal φSW to the gate of the MOS transistor T3 to turn this MOS transistor T3 off so that the base of the phototransistor PTr is brought into a floating state, and the signal φVPD is turned to the first voltage so that the MOS transistor T1 operates in a subthreshold region. In this state, as under the condition 1. described above, while the MOS transistor T5 in the individual pixels G11 to Gmn is off, the phototransistor PTr produces a photocurrent proportional to the amount of incident light, and the source voltage of the MOS transistor T1 is logarithmically proportional to the photocurrent.

Next, with identical timing, the pulse signal φS is fed to the gate of the MOS transistor T5 of the pixels G11 to Gmn, so that the voltage logarithmically proportional to the photocurrent is sampled and held at the gate of the MOS transistor T2. Then, the pulse signal φV is fed to the pixels G1 to Gmn sequentially to turn the MOS transistor T6 on, so that an output current logarithmically proportional to the photocurrent is delivered to the output signal line 6. After this signal (the output current) has been read out, the MOS transistor T6 is turned off.

(1-b) Sensitivity Variation Detection Operation

How the variation in sensitivity of the pixel is detected will be described below with reference to FIG. 31. After, as described above, the pulse signal φS is fed to the gate of the MOS transistor T5 of the pixels G11 to Gmn simultaneously so that the data of an image corresponding to one frame is sampled and held and then the pulse signal φV is fed to the gate of the MOS transistor T6 of the pixels G11 to Gmn sequentially so that the output signal is read out, first, with identical timing, a high level is fed as the signal φSW to the gate of the MOS transistor T3 of the pixels G11 to Gmn to turn this MOS transistor T3 on. When this MOS transistor T3 is turned on, a constant current is fed from the constant-current source 9 by way of the current feed line 8 to the base of the phototransistor PTr. It is to be noted that the timing chart of FIG. 31 deals only with a reset operation that takes place within a single pixel; in reality, the pulse signal φV is fed to the gate of the MOS transistor T6 of the individual pixels G11 to Gmn sequentially in the period after the signal φS has been turned to a low level before the signal φSW is turned to a high level.

When this constant current is fed from the constant-current source 9 to each pixel, a photocurrent that is determined by this current fed from the constant-current source 9 flows through the phototransistor PTr, and a voltage logarithmically proportional to the photocurrent that is determined by the constant-current source 9 appears at the source of the MOS transistor T1. Then, the pulse signal φS is fed to the gate of the MOS transistor T5 of the pixels G11 to Gmn so that the source voltage of the MOS transistor T1 is sampled and held at the gate of the MOS transistor T2. It is to be noted that, for the individual pixels G11 to Gmn, the signals φSW and φS are each switched simultaneously.

When this voltage is sampled and held at the gate of the MOS transistor T2 of the pixels G11 to Gmn, next the signal φSW is turned to a low level, and then the pulse signal φV is fed to the gate of the MOS transistor T6 of the pixels G11 to Gmn sequentially. As a result, from one pixel after another, an output current proportional to the gate voltage of the MOS transistor T2 is delivered to the output signal line 6 so as to be read out as serial data. After, in this way, the pulse signal φV is fed in so that the variation in sensitivity of each pixel is detected, the MOS transistors T6 is turned off. Here, the pulse signal φV is fed to the MOS transistor T6 of the individual pixels G11 to Gmn sequentially in the period after the signal φSW has been turned to a low level before the signal φS is turned to a high level.

(2) The Mode in Which the Photocurrent is Converted Linearly for Output

As under the condition 1. described above, the signal φVPD is turned to the second voltage. The signal φVPG is, as a binary voltage signal, switched between two levels so that, when it is at a high level, the MOS transistor T1 is turned on and, when it is at a low level, the MOS transistor T1 is turned off. Thus, the MOS transistor T1 functions as a resetting transistor, and the MOS transistor T2 functions as a signal amplification transistor.

(2-a) Image-Sensing Operation

First, a low level is fed as the signal φSW to the gate of the MOS transistor T3 to turn this MOS transistor T3 off so that the base of the phototransistor PTr is brought into a floating state. Then, the signal φVPG is turned to a high level so that, through the MOS transistor T1, the drain voltage of the MOS transistor T5 is reset. Then, the signal φVPG is turned to a low level, and moreover, in the individual pixels G11 to Gmn (FIG. 17) provided in the solid-state image-sensing device shown in FIG. 17, the MOS transistor T5 is turned off. In this state, a photocurrent flows through the phototransistor PTr, and thus, as under the condition 1. described above, the drain voltage of the MOS transistor T5 is linearly proportional to the photocurrent.

Next, with identical timing, the pulse signal φS is fed to the pixels G11 to Gmn, so that the drain voltage of the MOS transistor T5 is sampled and held at the gate of the MOS transistor T2. Then, the pulse signal φV is fed to the pixels G11 to Gmn sequentially to turn the signal φV to a high level and thereby turn the MOS transistor T6 on. As a result, a current linearly proportional to the photocurrent is delivered through the MOS transistors T2 and T6 to the output signal line 6. After this signal (the output current) proportional to the amount of incident light has been read out, the MOS transistor T6 is turned off.

(2-b) Sensitivity Variation Detection Operation

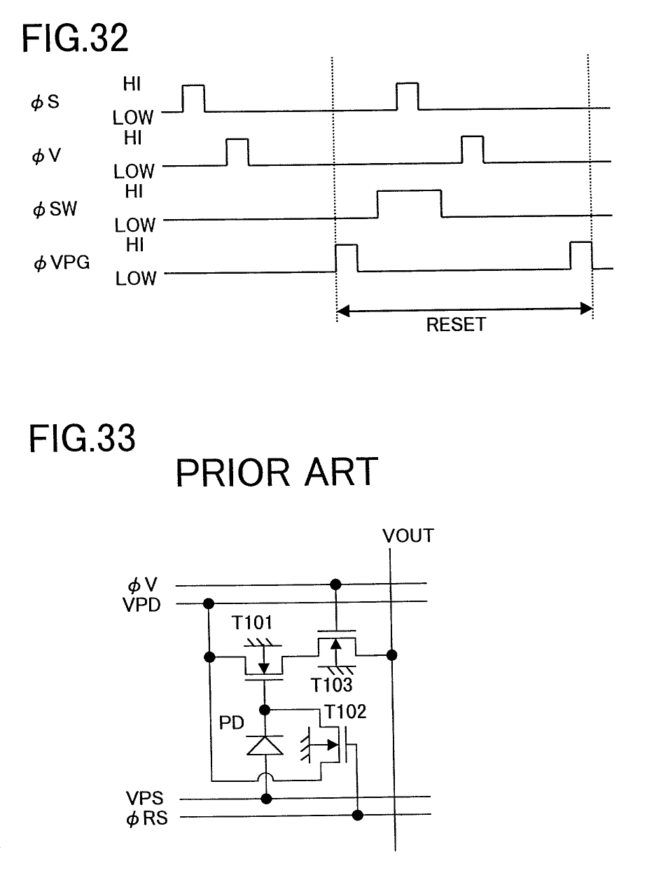

How the variation in sensitivity of the pixel is detected will be described below with reference to FIG. 32. After, as described above, the pulse signal φS is fed to the gate of the MOS transistor T5 of the pixels G11 to Gmn simultaneously so that the data of an image corresponding to one frame is sampled and held and then the pulse signal φV is fed to the gate of the MOS transistor T6 of the pixels G11 to Gmn sequentially so that the output signal is read out, first, the pulse signal φVPG is fed in to reset the drain voltage of the MOS transistor T5 of the pixels G11 to Gmn. It is to be noted that the timing chart of FIG. 32 deals only with a reset operation that takes place within a single pixel; in reality, the pulse signal φV is fed to the gate of the MOS transistor T6 of the individual pixels G11 to Gmn sequentially in the period after the signal φS has been turned to a low level before the signal φVPG is turned to a high level. Then, a high level is fed as the signal φSW to the gate of the MOS transistor T3 to turn this MOS transistor T3 on, so that a constant current is fed from the constant-current source 9 by way of the current feed line 8 to the base of the phototransistor PTr.

When this constant current is fed from the constant-current source 9 to each pixel, a photocurrent that is determined by this current fed from the constant-current source 9 flows through the phototransistor PTr, and thus a voltage linearly proportional to the photocurrent determined by the constant-current source 9 appears at the drain of the MOS transistor T5. Next, with identical timing, the pulse signal φS is fed to the gate of the MOS transistor T5 of the pixels G11 to Gmn so that this reset voltage is sampled and held at the gate of the MOS transistor T2.

When this reset voltage is sampled and held at the gate of the MOS transistor T2 of the pixels G11 to Gmn, then the signal φSW is turned to a low level, and the pulse signal φV is fed to the pixels G11 to Gmn sequentially to turn the MOS transistor T6 on. As a result, from one pixel after another, an output signal representing the variation in sensitivity of each pixel is delivered to the output signal line 6.

After, in this way, the pulse signal φV is fed in so that the variation in sensitivity of each pixel is detected, the pulse signal φVPG is fed to the MOS transistor T1 to reset the drain voltage of the MOS transistor T5. It is to be noted that, for the individual pixels G11 to Gmn, the signals φSW, φS, and φVPG are each switched simultaneously. It is also to be noted that the pulse signal φV is fed to the gate of the MOS transistor T6 of the individual pixels G11 to Gmn sequentially in the period after the signal φSW has been turned to a low level before the signal φVPG is turned to a high level.

In this embodiment, it is necessary to store the output signals read out from the individual pixels G11 to Gmn in an image-sensing operation and in a sensitivity variation detection operation, as image data and compensation data respectively, in a memory or the like that can store at least the whole of one of those two sets of data. For example, by storing pixel-to-pixel compensation data in a memory, it is possible to correct image data with the compensation data stored in the memory and thereby eliminate pixel-to-pixel variations from the image data.

In the sixth to fifteenth embodiments described above, as signals obtained when variations in sensitivity among the individual pixels are detected or when the individual pixels are reset are delivered from one pixel after another to the output signal line 6, those signals are fed out serially to the succeeding circuit so as to be stored as pixel-by-pixel compensation data in a memory provided therein. Then, by correcting pixel by pixel the signals obtained during an actual image sensing operation with the compensation data thus stored, it is possible to eliminate variations in sensitivity among the individual pixels from their output signals. This correction may be realized by providing memories, such as line memories, within the image-sensing device.

In the sixth to ninth, fourteenth, and fifteenth embodiments, the pixel may be so configured as to include an integrator circuit by connecting a capacitor, the gate of a signal amplifying MOS transistor, or the like to the source of the MOS transistor T2. In the first to fifteenth embodiments, the reading of the signal from each pixel may be achieved by the use of a charge-coupled device (CCD). In that case, the transfer of electric charge to the CCD is achieved by providing a potential barrier with a variable potential level that corresponds to the MOS transistor T6 that serves as a switch for selecting a row.

In all the embodiments described above, N-channel MOS transistors are used as the MOS transistors T1 to T10 and an npn-type transistor is used as the phototransistor PTr. However, it is also possible to use P-channel MOS transistors as the MOS transistors T1 to T10 and a pnp-type phototransistor as the phototransistor PTr. In that case, also in the pixel configuration shown in FIG. 1 or 17, P-channel MOS transistors are used as the MOS transistors Q1 and Q2. A solid-state image-sensing device composed of P-channel MOS transistors and a pnp-type phototransistor in this way has an inverted circuit configuration and operates in an inverted manner, but functions in substantially the same manner.

In a solid-state image-sensing device according to the present invention, phototransistors are used as the photosensitive elements of its photoelectric conversion means. This permits photocurrents to be output as amplified electric signals, and thus makes it possible to perform image sensing with high sensitivity. Moreover, it is possible to freely switch the operation of the photoelectric conversion means between natural-logarithmic conversion and linear conversion irrespective of the brightness of the subject. Accordingly, it is possible, for example, to switch to logarithmic conversion when shooting a subject having a wide brightness range and to linear conversion when shooting a dimly-lit subject or a subject having a narrow brightness range. This makes it possible to shoot subjects of varying brightness, from those dimly-lit to those brightly-lit, with high definition.

In a solid-state image-sensing device according to the present invention, phototransistors are used as photosensitive elements, and MOS transistors are made to operate in a subthreshold region so that the electric signals from the phototransistors are natural-logarithmically converted for output. This makes it possible to realize a solid-state image-sensing device that offers high sensitivity and a wide dynamic range despite having a simple circuit configuration that permits flexible designing of circuit configuration. In particular, by providing a constant-current source that feeds a constant current to the base electrode of the phototransistors, it is possible to feed an identical constant current to the control electrode of the phototransistor of each pixel and thereby obtain an output signal representing the amplification factor of each phototransistor. This makes it possible to detect variations in sensitivity among the individual pixels that result from variations in the amplification factor among those phototransistors without illuminating the pixels with uniform light as practiced conventionally. Thus, it is possible to obtain high-definition images free from variations in sensitivity among the pixels.

Moreover, by permitting switching of the direct-current voltage applied to the constant-current source, it is possible to switch the amplification factor of the phototransistors. This makes it possible to switch their sensitivity in accordance with the brightness of the subject to be shot. Moreover, each pixel is provided with a switch that permits an image-sensing operation to be performed simultaneously in all the pixels of the solid-state image-sensing device. This makes it possible to obtain high-definition image signals free of temporal errors.

What is claimed is:

1. A solid-state image-sensing device comprising:
a phototransistor, having a control electrode kept in a floating state, for producing an electric signal by amplifying a photocurrent that appears at the control electrode in proportion to an amount of incident light; and
a first transistor, connected in series with the phototransistor, for receiving the electric signal amplified by the phototransistor, wherein the first transistor is made to operate in a subthreshold region so that the electric signal output from the phototransistor is so converted as to be fed out as a signal logarithmically proportional to the amount of incident light.

2. A solid-state image-sensing device as claimed in claim 1,
wherein, when the first transistor is brought into a non-operating state, the electric signal output from the phototransistor is so converted as to be fed out as a signal linearly proportional to the amount of incident light.

3. A solid-state image-sensing device as claimed in claim 1, further comprising:
a second transistor receiving at a first electrode a direct-current voltage, having a control electrode connected to a control electrode of the first transistor, and outputting at a second electrode the electric signal.

4. A solid-state image-sensing device as claimed in claim 3, further comprising:
a switch, connected between the control electrode of the first transistor and the control electrode of the second transistor, for electrically connecting and disconnecting the control electrode of the first transistor to and from the control electrode of the second transistor.

5. A solid-state image-sensing device as claimed in claim 1, further comprising:
a second transistor receiving at a first electrode a direct-current voltage, having a control electrode connected to a node at which a first electrode of the phototransistor and a second electrode of the first transistor are connected together, and outputting at a second electrode the electric signal;.

6. A solid-state image-sensing device as claimed in claim 5, further comprising:
a switch, connected between the node at which the first electrode of the phototransistor and the second electrode of the first transistor are connected together and the control electrode of the second transistor, for electrically connecting and disconnecting the node to and from the control electrode of the second transistor.

7. An solid-state image-sensing device comprising:
a photoelectric conversion portion having a photosensitive element that generates an electric signal proportional to an amount of incident light; and
a signal delivery path by way of which an output signal from the photoelectric conversion portion is delivered to an output signal line,
wherein the photosensitive element is a phototransistor that generates the electric signal by amplifying a photocurrent that appears at a control electrode thereof in proportion to the amount of incident light, and
wherein the photoelectric conversion portion can be switched between a first state in which the photoelectric conversion portion converts the electric signal generated by the phototransistor into a signal linearly proportional to the amount of incident light and a second state in which the photoelectric conversion portion converts the electric signal generated by the phototransistor into a signal naturallogarithmically proportional to the amount of incident light.

8. A solid-state image-sensing device as claimed in claim 7, further comprising:
a resetting portion for initializing the photoelectric conversion portion after the photoelectric conversion portion has output the electric signal to the output signal line by operating in the first state.

9. A solid-state image-sensing device as claimed in claim 7, further comprising:
an amplifying transistor for amplifying the output signal from the photoelect ric conversion porintion,
wherein an output signal from the amplifying transistor is delivered by way of the signal delivery path to the output signal line.

10. A solid-state image-sensing device comprising:
a plurality of pixels each comprising:
a phototransistor for producing an electric signal by amplifying a photocurrent that appears at a control electrode thereof in proportion to an amount of incident light;
a first transistor, connected in series with the phototransistor, for receiving the electric signal amplified by the phototransistor; and
a first switch for switching a bias applied to the control electrode of the phototransistor,
wherein, when image sensing is performed, the first switch is so set as to keep the control electrode of the phototransistor in a floating state and thereby make the first transistor operate in a subthreshold region so that the electric signal is so converted as to be fed out as a signal natural-logarithmically proportional to the amount of incident light, and
wherein, when no image sensing is performed, the first switch is so set as to apply a forward bias to the control electrode of the phototransistor so that, from the individual pixels, electric signals are obtained with which to correct variations in outputs of the individual pixels.

11. A solid-state image-sensing device as claimed in claim 10,
wherein the first switch permits also another bias different from the forward bias to be applied to the control electrode of the phototransistor so as to permit image sensing at different amplification factors.

12. A solid-state image-sensing device as claimed in claim 10, further comprising:
a second transistor receiving at a first electrode a direct-current voltage, having a control electrode connected to a control electrode of the first transistor, and outputting at a second electrode the electric signal.

13. A solid-state image-sensing device as claimed in claim 12, further comprising:
a second switch, connected between the control electrode of the first transistor and the control electrode of the second transistor, for electrically connecting and disconnecting the control electrode of the first transistor to and from the control electrode of the second transistor,
wherein the second switch is operated with identical timing in all of the plurality of pixels so that image sensing is performed with identical timing in all of the plurality of pixels.

14. A solid-state image-sensing device as claimed in claim 10, further comprising:
a second transistor receiving at a first electrode a direct-current voltage, having a control electrode connected to a node at which a first electrode of the phototransistor and a second electrode of the first transistor are connected together, and outputting at a second electrode the electric signal;.

15. A solid-state image-sensing device as claimed in claim 14, further comprising:
a second switch, connected between the node at which the first electrode of the phototransistor and the second electrode of the first transistor are connected together and the control electrode of the second transistor, for electrically connecting and disconnecting the node to and from the control electrode of the second transistor,
wherein the second switch is operated with identical timing in all of the plurality of pixels so that image sensing is performed with identical timing in all of the plurality of pixels.

16. A solid-state image-sensing device comprising:
a plurality of pixels arranged in a matrix, the pixels each comprising:
a phototransistor, having a base electrode kept in a floating state and receiving at a first electrode a direct-current voltage, for amplifying a photocurrent that appears at the base electrode in proportion to an amount of incident light;
a first MOS transistor having a first electrode and a gate electrode connected to a second electrode of the phototransistor; and
a second MOS transistor having a gate electrode connected to the gate electrode of the first MOS transistor,
wherein the first MOS transistor is made to operate in a subthreshold region below a threshold level thereof so that an electric signal output from the phototransistor is converted into a signal natural-logarithmically proportional to the amount of incident light and is then output from a second electrode of the second MOS transistor.

17. A solid-state image-sensing device as claimed in claim 16,
wherein the first and second MOS transistors are both N-channel MOS transistors and the phototransistor is an npn-type phototransistor.

18. A solid-state image-sensing device comprising:
a plurality of pixels arranged in a matrix; and
a constant-current source for supplying a constant current to the individual pixels,
the pixels each comprising:
a phototransistor, receiving at a first electrode a direct-current voltage, for amplifying a photocurrent that appears at a base electrode thereof in proportion to an amount of incident light;
a first MOS transistor having a first electrode and a gate electrode connected to a second electrode of the phototransistor;
a second MOS transistor having a gate electrode connected to the gate electrode of the first MOS transistor; and
a third MOS transistor having a first electrode connected to the constant-current source and having a second electrode connected to the base electrode of the phototransistor,
wherein, when image sensing is performed, the third MOS transistor is turned off and the first MOS transistor is made to operate in a subthreshold region below a threshold level thereof so that an electric signal output from the phototransistor is converted into a signal natural-logarithmically proportional to the amount of incident light and is then output from a second electrode of the second MOS transistor, and
wherein, when variations in sensitivity among the individual pixels are detected, the third MOS transistor is turned on.

19. A solid-state image-sensing device as claimed in claim 18,
wherein the first, second, and third MOS transistors are all N-channel MOS transistors and the phototransistor is an npn-type phototransistor.

20. A solid-state image-sensing device comprising:
a plurality of pixels arranged in a matrix, the pixels each comprising:
an npn-type phototransistor, having a base electrode kept in a floating state and receiving at an emitter electrode a direct-current voltage, for amplifying a photocurrent that appears at the base electrode in proportion to an amount of incident light;
a first MOS transistor having a second electrode connected to a collector electrode of the phototransistor; and
a second MOS transistor having a gate electrode connected to the second electrode of the first MOS transistor,
wherein the first MOS transistor is made to operate in a subthreshold region below a threshold level thereof so that an electric signal output from the phototransistor is converted into a signal natural-logarithmically proportional to the amount of incident light and is then output from a second electrode of the second MOS transistor.

21. A solid-state image-sensing device as claimed in claim 20,
wherein, when the first MOS transistor is turned off, the individual pixels operate in a first state in which the photocurrent is converted into a signal linearly proportional to the amount of incident light, and
wherein, when the first MOS transistor is turned on and is made to operate in the subthreshold region, the individual pixels operate in a second state in which the photocurrent is converted into a signal logarithmically proportional to the amount of incident light.

22. A solid-state image-sensing device comprising:
a plurality of pixels arranged in a matrix; and
a constant-current source for supplying a constant current to the individual pixels,
the pixels each comprising:
an npn-type phototransistor, receiving at an emitter electrode a directcurrent voltage, for amplifying a photocurrent that appears at a base electrode thereof in proportion to an amount of incident light;
a first MOS transistor having a second electrode connected to a collector electrode of the phototransistor;
a second MOS transistor having a gate electrode connected to the second electrode of the first MOS transistor; and
a third MOS transistor having a first electrode connected to the constant-current source and having a second electrode connected to the base electrode of the phototransistor,
wherein, when image sensing is performed, the third MOS transistor is turned off and the first MOS transistor is made to operate in a subthreshold region below a threshold level thereof so that an electric signal output from the phototransistor is converted into a signal natural-logarithmically proportional to the amount of incident light and is then output from a second electrode of the second MOS transistor, and
wherein, when variations in sensitivity among the individual pixels are detected, the third MOS transistor is turned on.

23. A solid-state image-sensing device as claimed in claim 22,
wherein a direct-current voltage applied to the constant-current source can be switched so that, by turning the third MOS transistor on and in addition switching that direct-current voltage in such a way that the phototransistor receives another bias different from a forward bias thereof, an amplification factor of the photodiode can be switched.
